(19) United States
(12) Patent Application Publication
(10) Pub. No.: US 2026/0157179 A1
(43) Pub. Date: Jun. 4, 2026

(54) CHIP PACKAGE STRUCTURE WITH HEAT SINK AND METHOD FOR FORMING THE SAME

(71) Applicant: Taiwan Semiconductor Manufacturing Company, Ltd., Hsinchu (TW)

(72) Inventors: Sing-Da JIANG, Taichung City (TW); Shih-Wei LIU, Chiayi City (TW); Tsun-Yen WU, Hsinchu County (TW); Kathy Wei YAN, Hsinchu (TW)

(73) Assignee: Taiwan Semiconductor Manufacturing Company, Ltd., Hsinchu (TW)

(21) Appl. No.: 18/964,206

(22) Filed: Nov. 29, 2024

(51) Int. Cl. H01L 23/473; H01L 21/308; H01L 21/50; H01L 23/42; H01L 25/00; H01L 25/065

(52) U.S. Cl. CPC H10W 40/47; H10W 40/70; H10W 90/00; H10W 95/00; H10P 50/691; H10W 90/26; H10W 90/288; H10W 90/297; H10W 90/722

(57) ABSTRACT

A method for forming a chip package structure is provided. The method includes providing a chip having a semiconductor substrate having a front surface and a back surface. The method includes partially removing the semiconductor substrate from the back surface to form a recess in the semiconductor substrate. The method includes bonding a heat sink to the chip. The heat sink has a first channel and a second channel, and the first channel and the second channel pass through the heat sink and connect the recess.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, chips generate more heat. Therefore, it is a challenge to form packages with good heat dissipation performance.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1L are cross-sectional views of various stages of a process for forming a chip package structure, in accordance with some embodiments.

FIG. 1E-1 is a top view of the chip of FIG. 1E, in accordance with some embodiments.

FIG. 1E-2 is a top view of a pillar of the chip of FIG. 1E, in accordance with some embodiments.

FIG. 1E-3 is a cross-sectional view illustrating the chip along a sectional line II-II′ in FIG. 1E-1, in accordance with some embodiments.

FIG. 1F-1 is a top view of the chip of FIG. 1F, in accordance with some embodiments.

FIG. 1F-2 is a cross-sectional view illustrating the chip along a sectional line II-II′ in FIG. 1F-1, in accordance with some embodiments.

FIG. 1I-1 is a top view of the chip package structure of FIG. 1I, in accordance with some embodiments.

FIG. 1J-1 is a top view of the chip package structure of FIG. 1J, in accordance with some embodiments.

FIG. 1K-1 is a top view of the chip package structure of FIG. 1K, in accordance with some embodiments.

FIG. 1K-2 is a cross-sectional view illustrating the chip package structure along a sectional line II-II′ in FIG. 1K-1, in accordance with some embodiments.

FIG. 1K-3 is a top view of a first region of the chip package structure of FIG. 1K-1, in accordance with some embodiments.

FIG. 1K-4 is a cross-sectional view illustrating the chip package structure along a sectional line III-III′ in FIG. 1K-1, in accordance with some embodiments.

FIG. 1K-5 is a top view of a second region of the chip package structure of FIG. 1K-1, in accordance with some embodiments.

FIG. 1L-1 is a top view of the chip package structure of FIG. 1L, in accordance with some embodiments.

FIG. 1L-2 is a cross-sectional view illustrating the chip package structure along a sectional line II-II′ in FIG. 1L-1, in accordance with some embodiments.

FIG. 1L-3 is a cross-sectional view illustrating the chip package structure along a sectional line III-III′ in FIG. 1L-1, in accordance with some embodiments.

FIG. 1L-4 is a top view of the chip package structure of FIG. 1L, in accordance with some embodiments.

FIG. 1L-5 is a cross-sectional view illustrating the chip package structure along a sectional line IV-IV′ in FIG. 1L-4, in accordance with some embodiments.

FIG. 1L-6 is a cross-sectional view illustrating the chip package structure along a sectional line V-V′ in FIG. 1L-4, in accordance with some embodiments.

FIG. 1L-7 is a cross-sectional view illustrating the chip package structure along a sectional line VI-VI′ in FIG. 1L-4, in accordance with some embodiments.

FIG. 1L-8 is a cross-sectional view illustrating the chip package structure along a sectional line VII-VII′ in FIG. 1L-4, in accordance with some embodiments.

FIGS. 2A-2C are cross-sectional views of various stages of a process for forming a chip package structure, in accordance with some embodiments.

FIG. 2A-1 is a top view of the chip package structure of FIG. 2A, in accordance with some embodiments.

FIG. 2B-1 is a top view of the chip package structure of FIG. 2B, in accordance with some embodiments.

FIG. 2B-2 is a cross-sectional view illustrating the chip package structure along a sectional line II-II′ in FIG. 2B-1, in accordance with some embodiments.

FIG. 2C-1 is a top view of the chip package structure of FIG. 2C, in accordance with some embodiments.

FIG. 2C-2 is a cross-sectional view illustrating the chip package structure along a sectional line II-II′ in FIG. 2C-1, in accordance with some embodiments.

FIG. 2C-3 is a cross-sectional view illustrating the chip package structure along a sectional line III-III′ in FIG. 2C-1, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

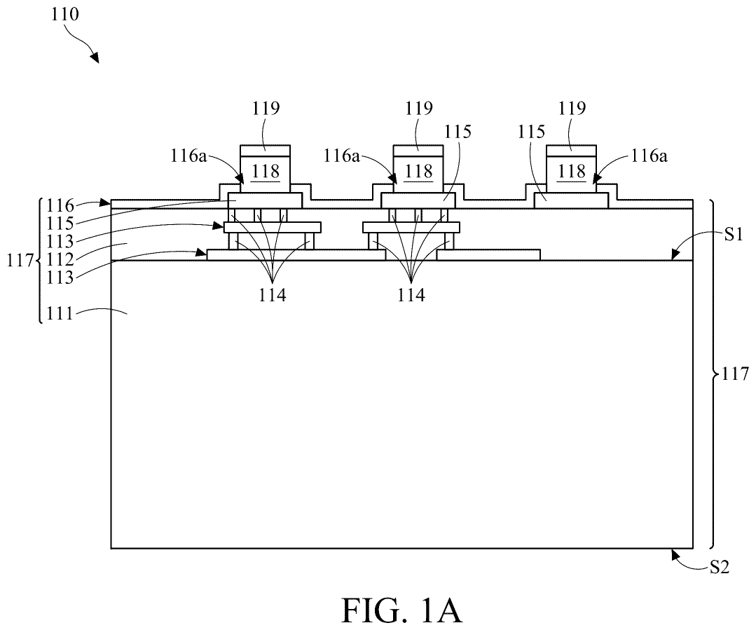

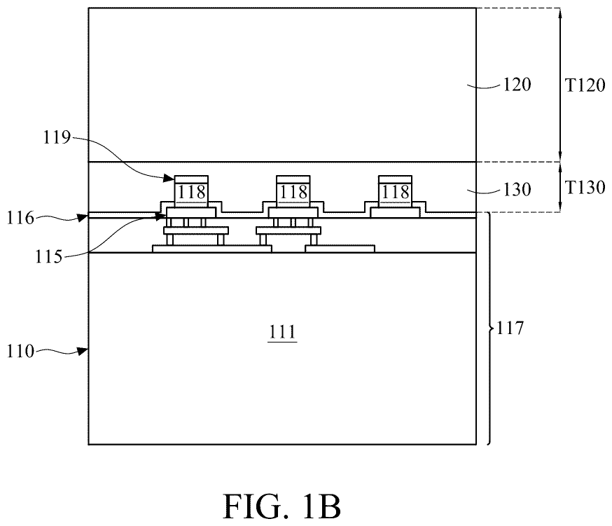

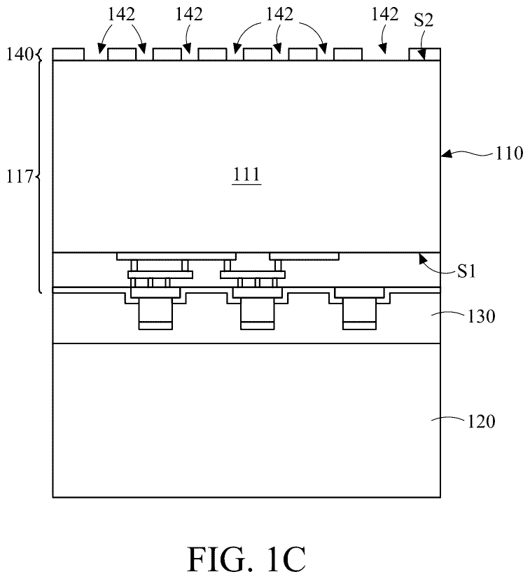

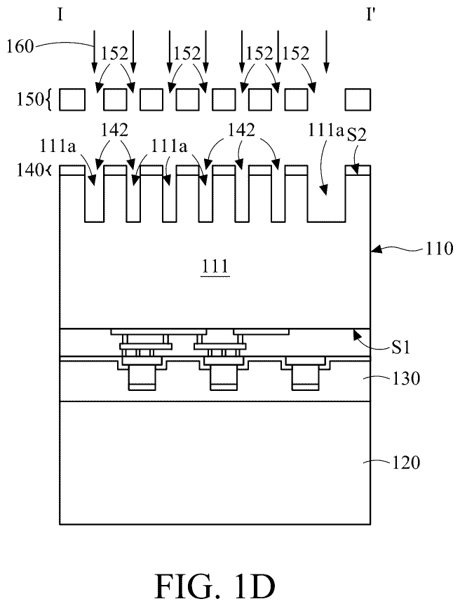

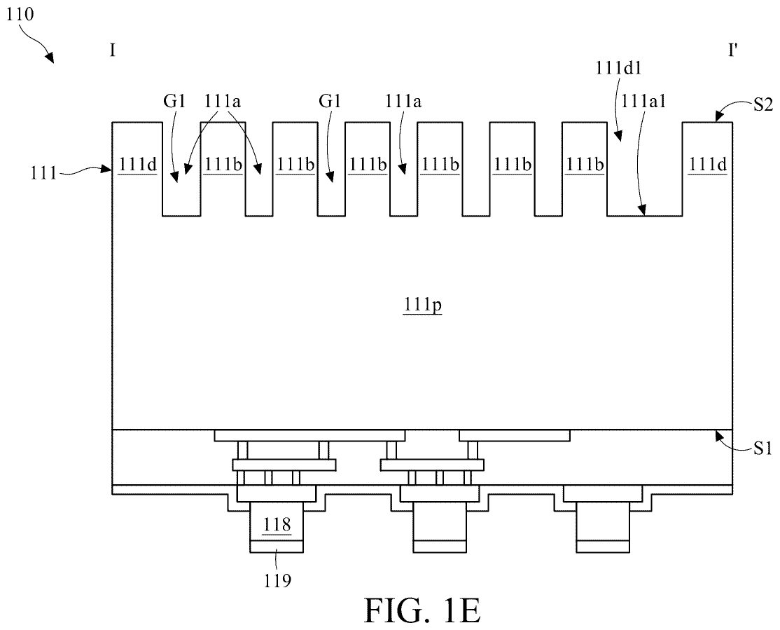

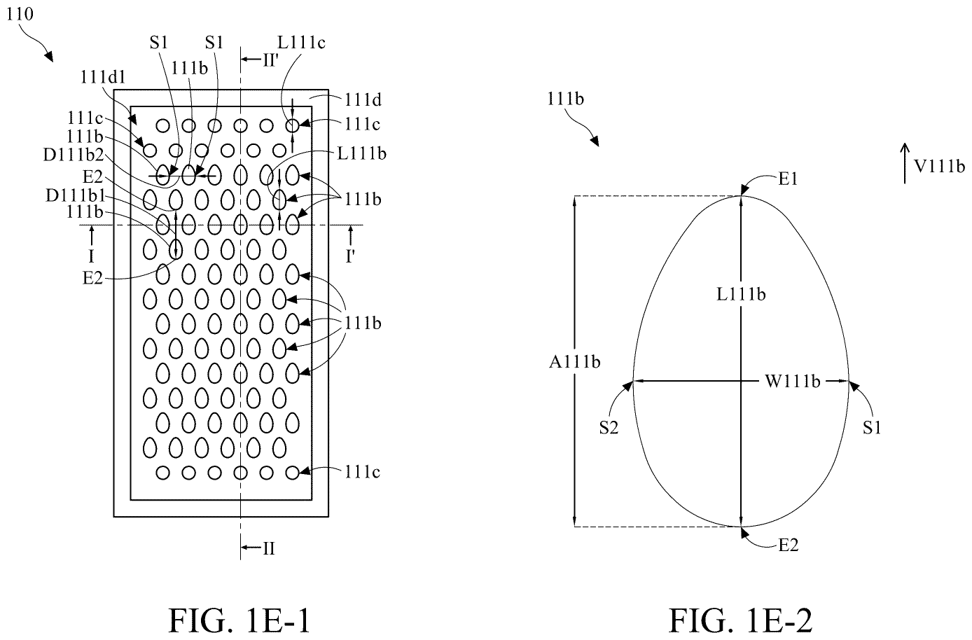

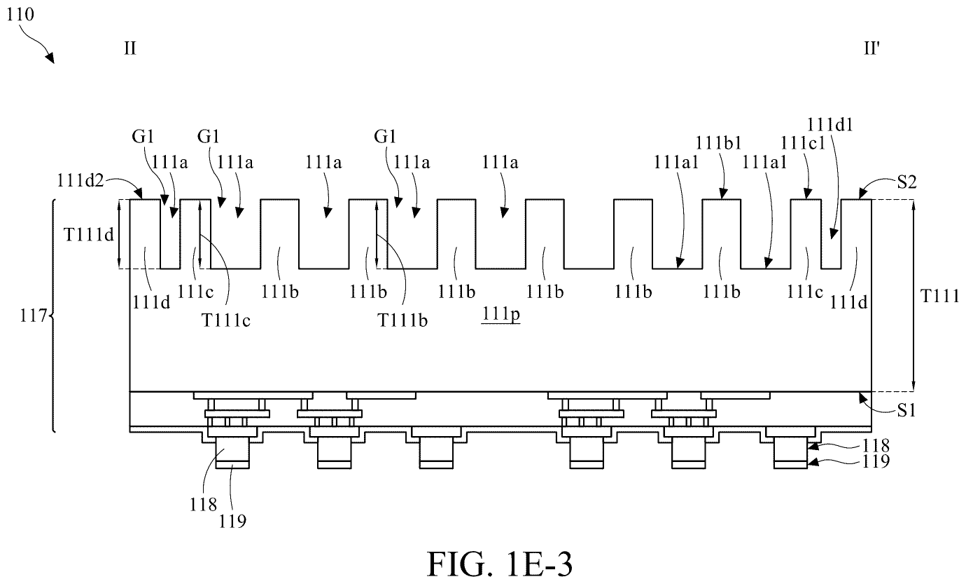

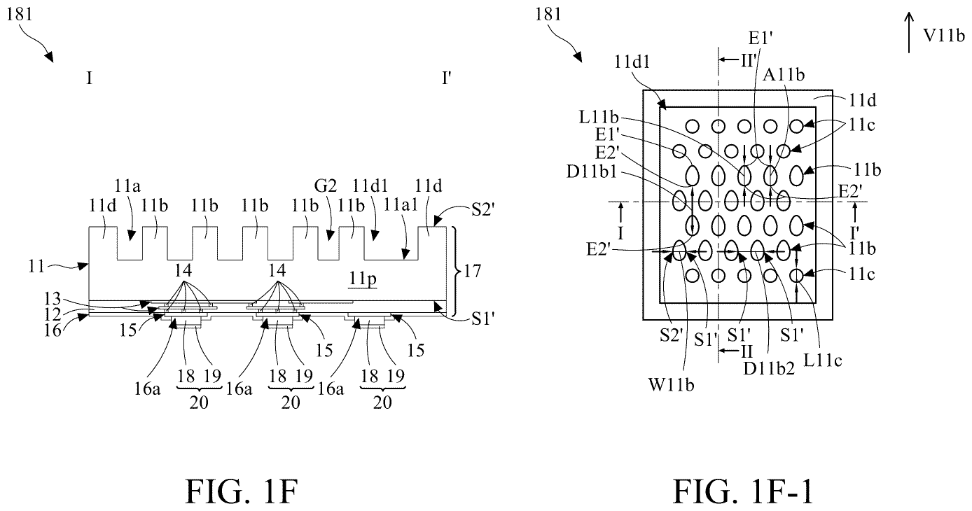

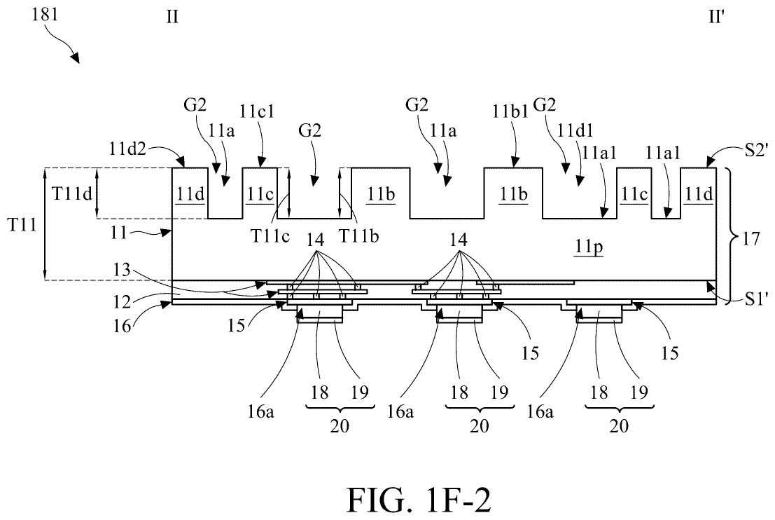

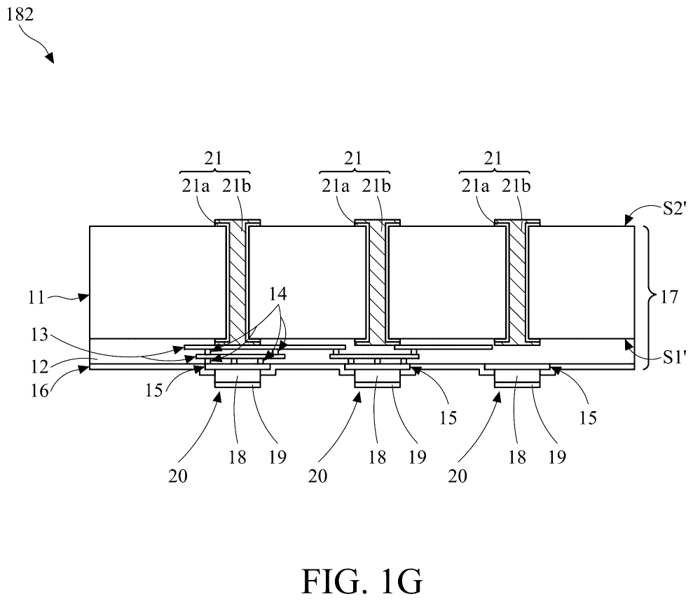

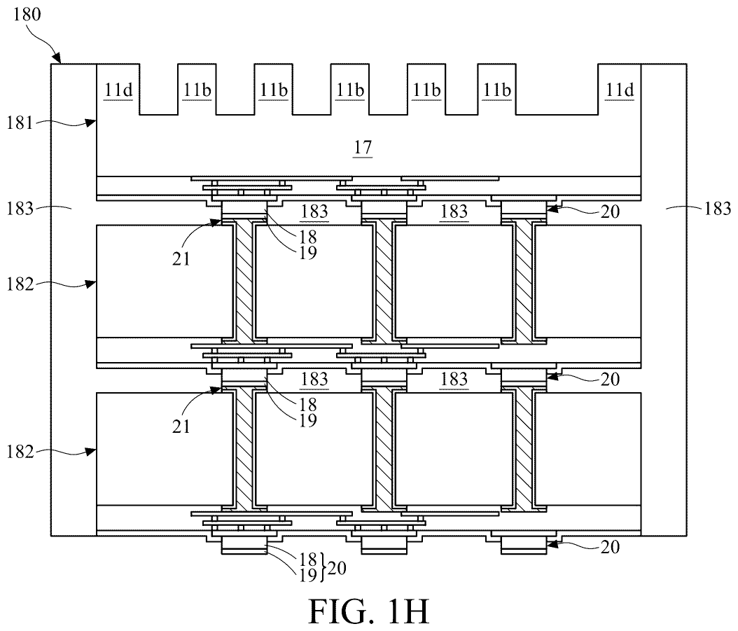

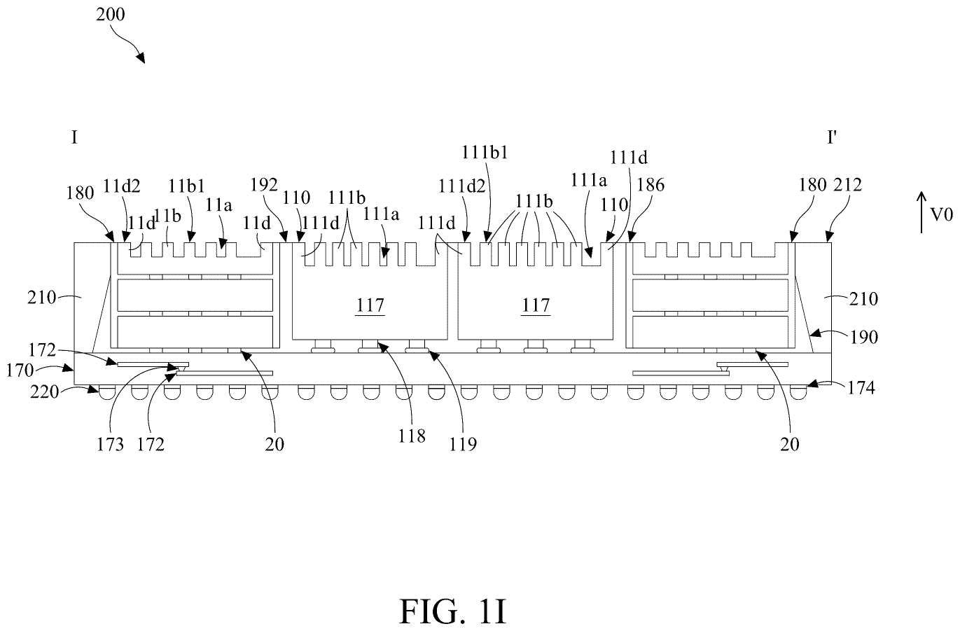

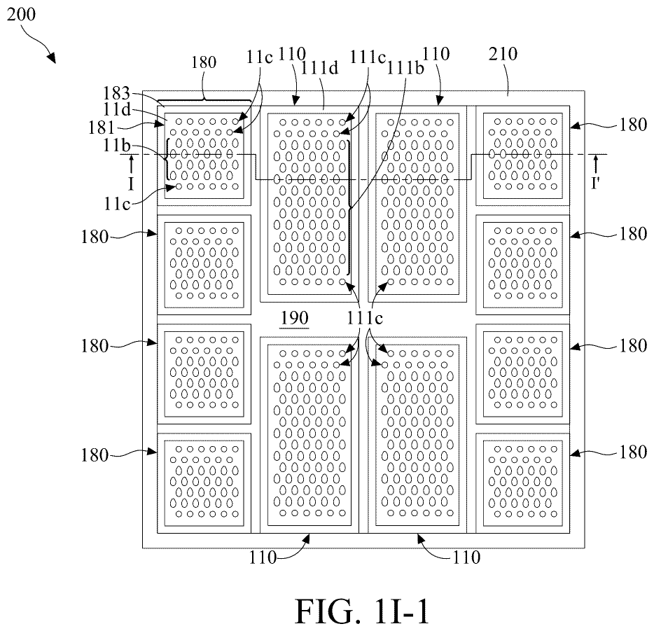

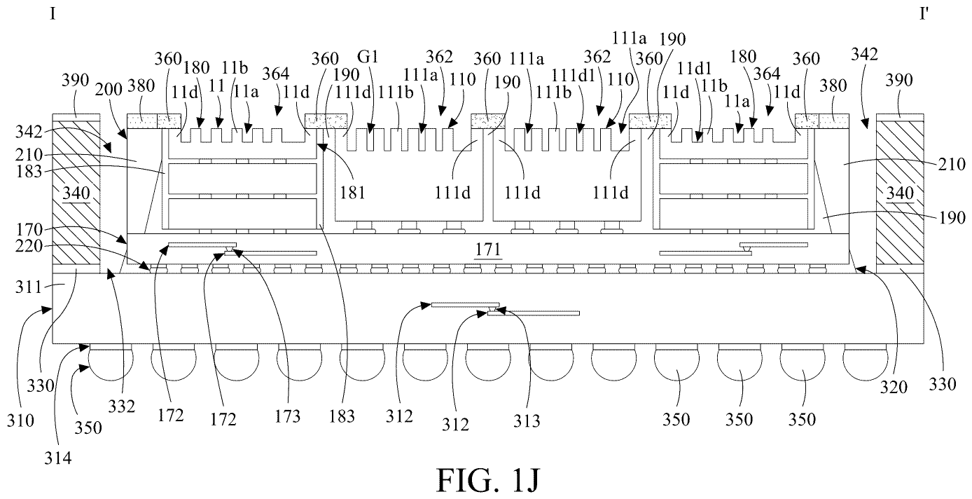

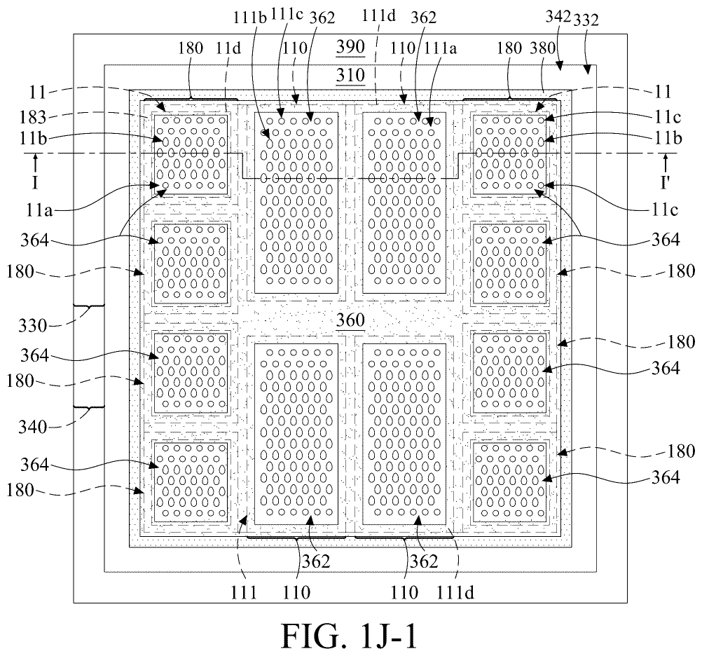

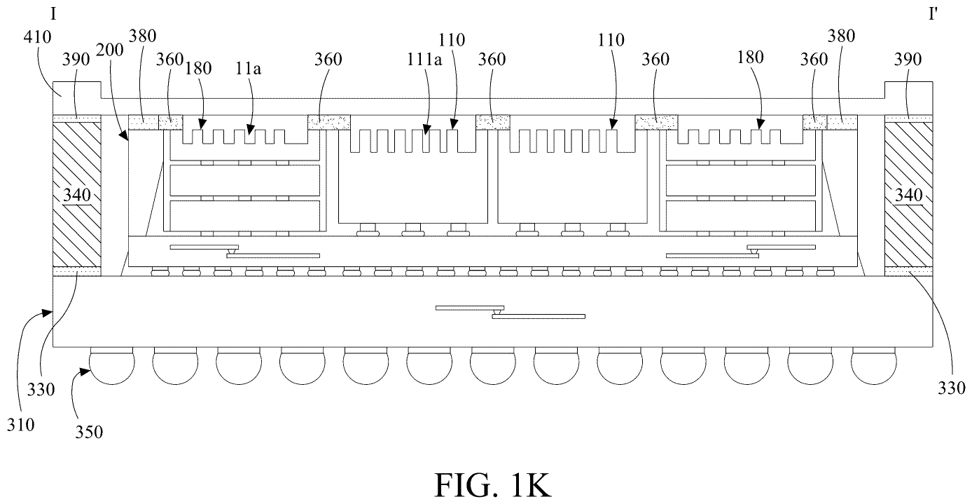

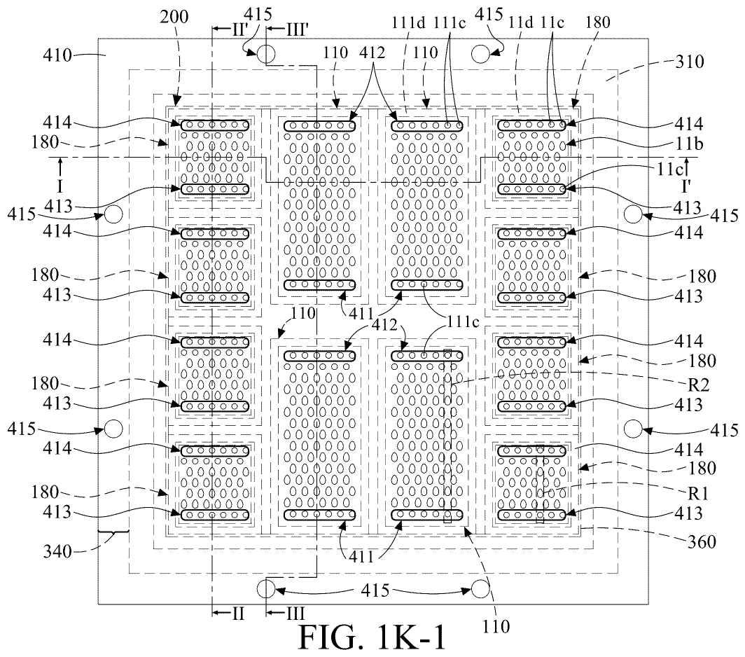

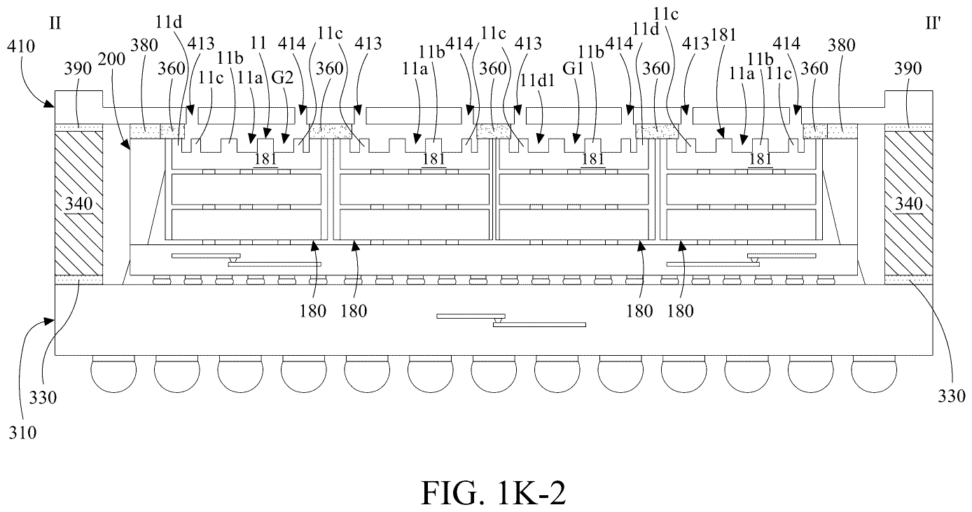

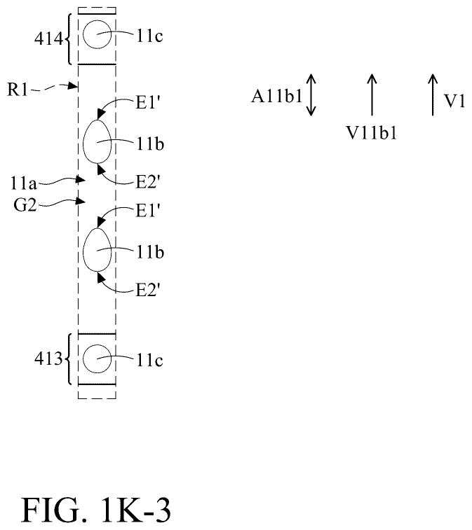

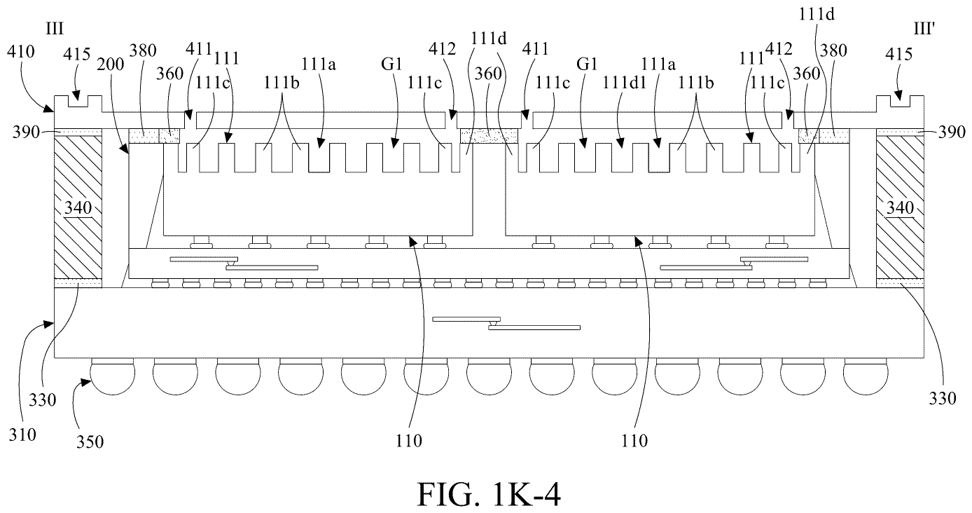

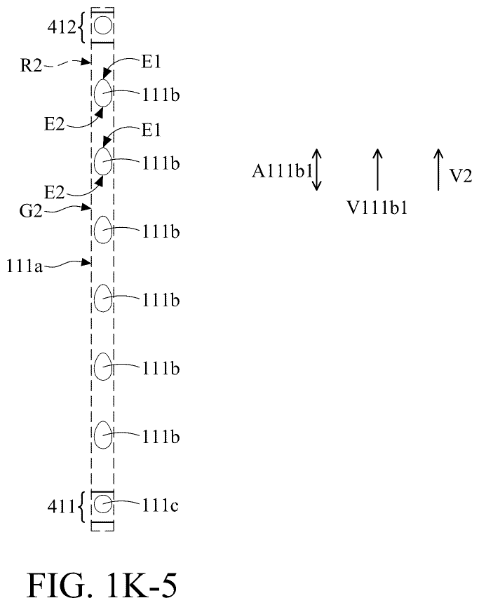

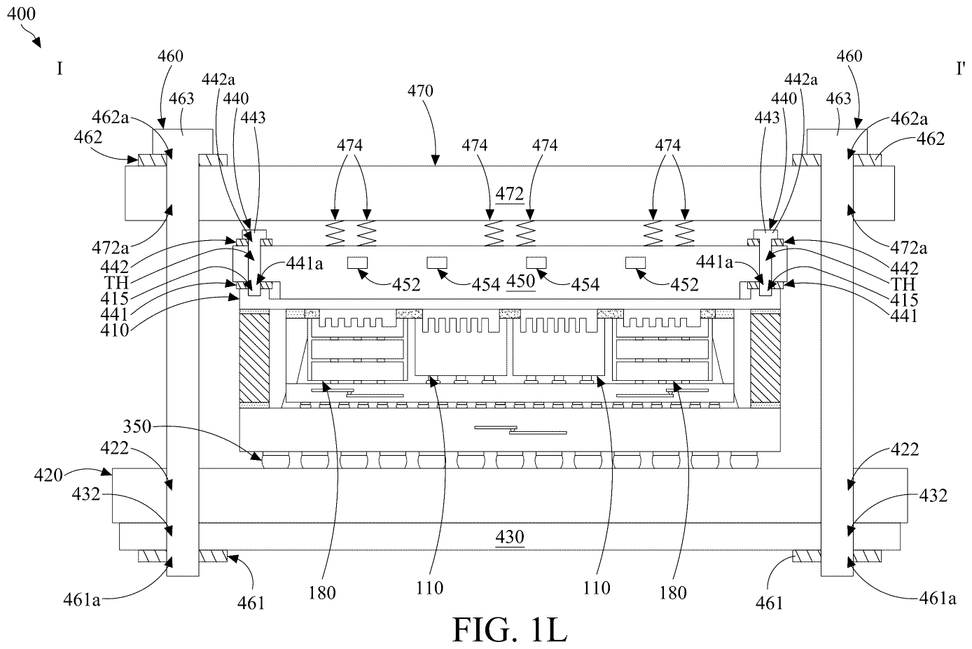

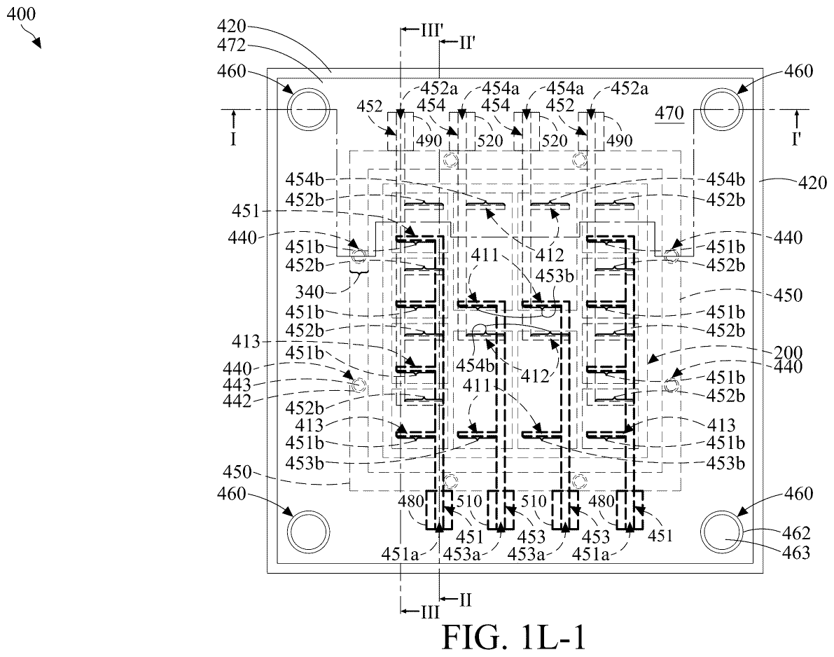

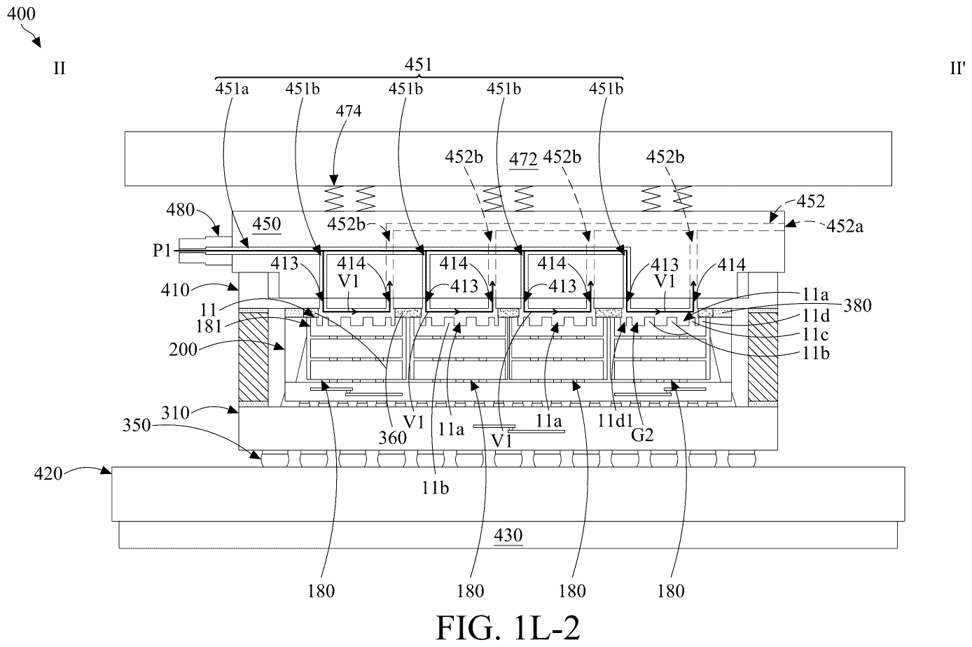

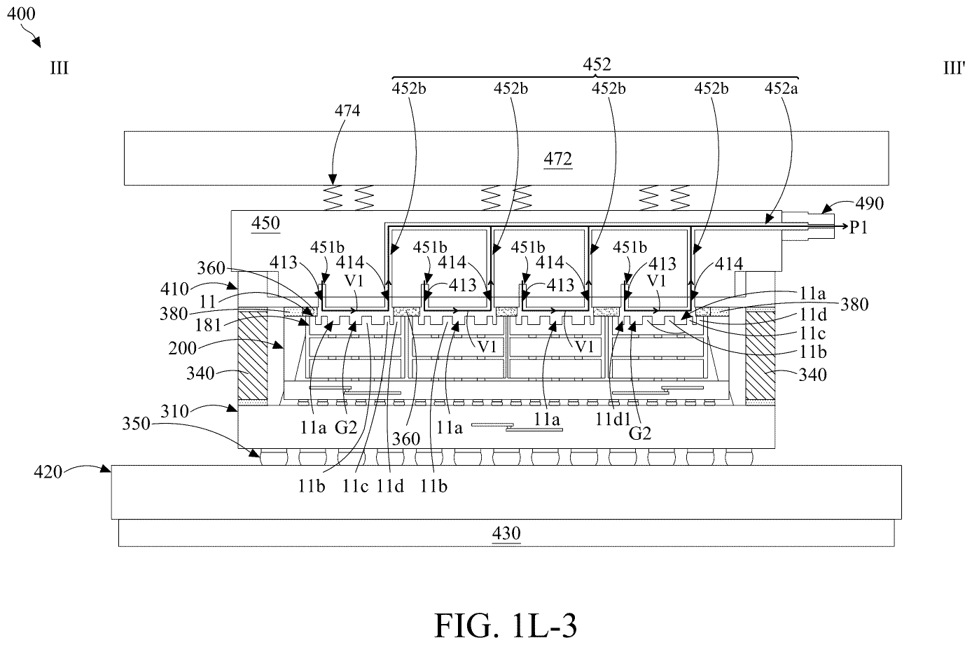

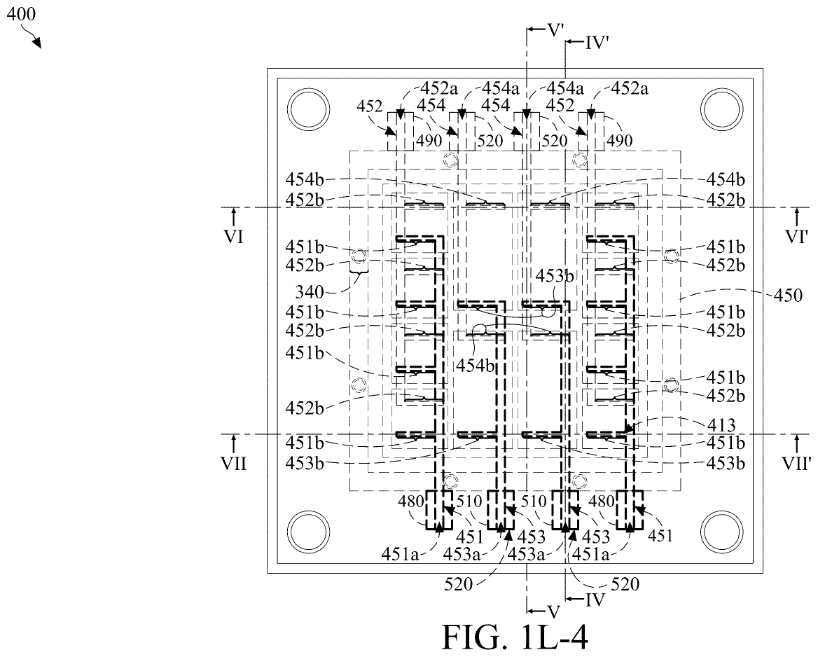

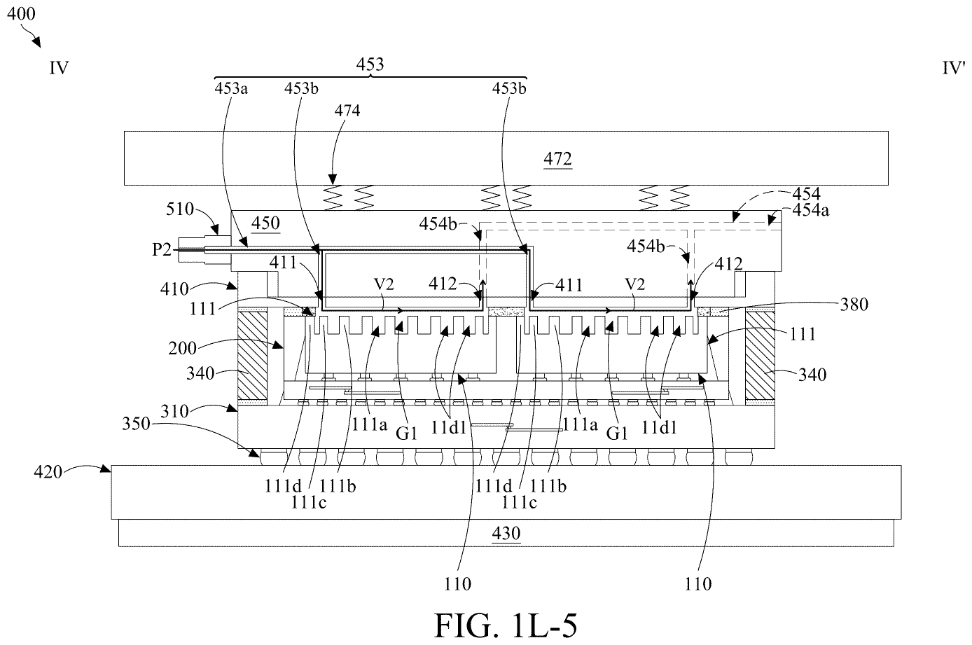

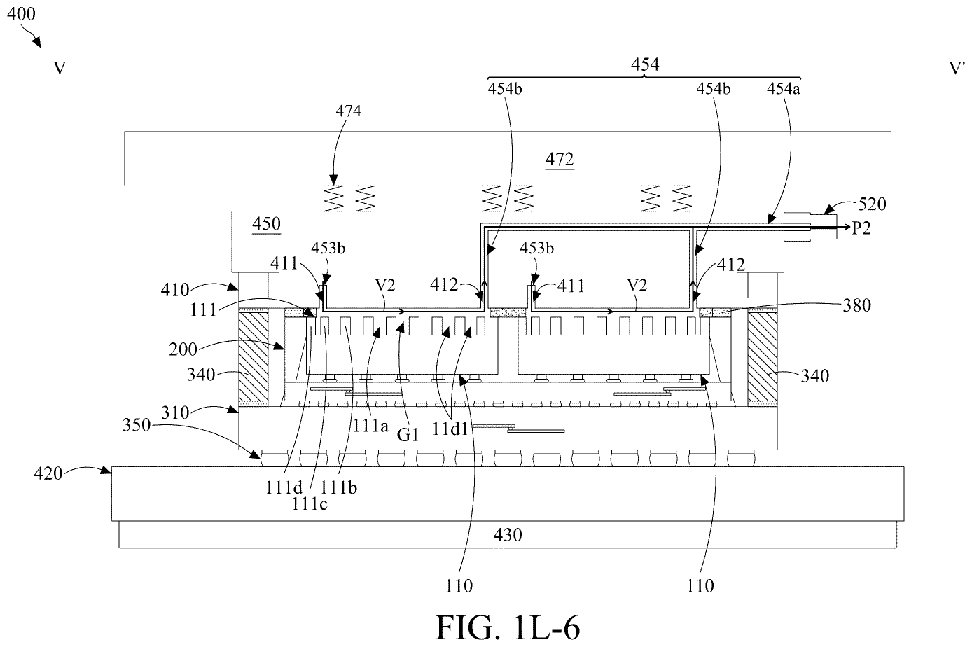

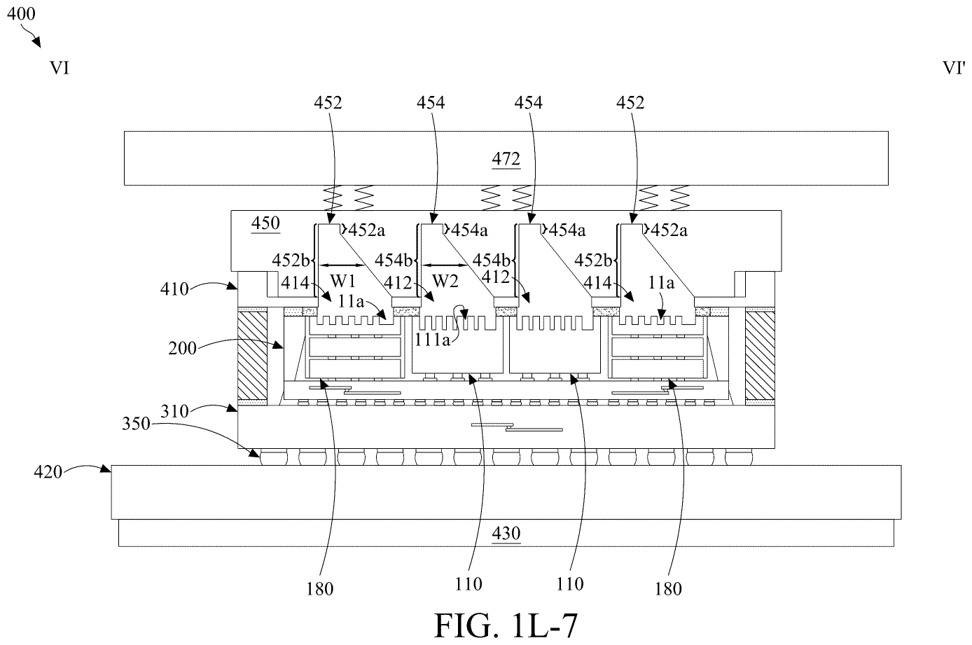

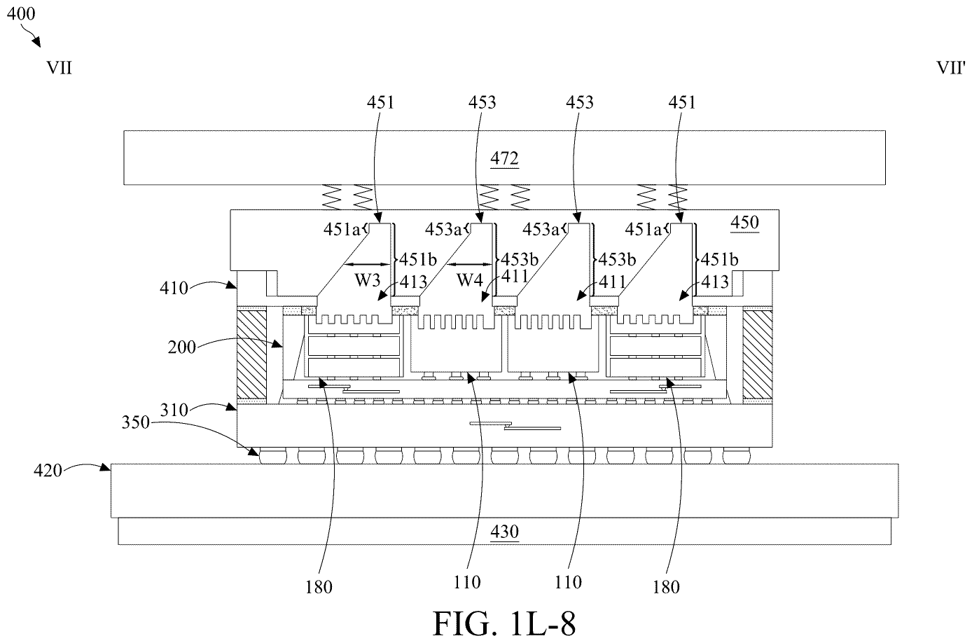

FIGS. 1A-1L are cross-sectional views of various stages of a process for forming a chip package structure, in accordance with some embodiments. As shown in FIG. 1A, a chip 110 is provided, in accordance with some embodiments. The chip 110 includes a semiconductor substrate 111, a dielectric layer 112, wiring layers 113, conductive vias 114, conductive pads 115, a passivation layer 116, conductive bumps 118, and a solder layer 119, in accordance with some embodiments. The semiconductor substrate 111 has a front surface S1 and a back surface S2, in accordance with some embodiments.

In some embodiments, the semiconductor substrate 111 is made of an elementary semiconductor material including silicon or germanium in a single crystal structure, a polycrystal structure, or an amorphous structure. In some other embodiments, the semiconductor substrate 111 is made of a compound semiconductor, such as silicon carbide, gallium arsenide, gallium phosphide, indium phosphide, indium arsenide, an alloy semiconductor, such as SiGe or GaAsP, or a combination thereof. The semiconductor substrate 111 may also include multi-layer semiconductors, semiconductor on insulator (SOI) (such as silicon on insulator or germanium on insulator), or a combination thereof.

In some embodiments, various devices (not shown) are formed in and/or over the semiconductor substrate 111. Examples of the various devices include active devices, passive devices, other suitable devices, or a combination thereof. The active devices may include transistors or diodes formed at a surface of the semiconductor substrate 111. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various devices. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 111. The isolation features are used to surround active regions and electrically isolate various devices formed in and/or over the semiconductor substrate 111 in the active regions. In some embodiments, the isolation features include shallow trench isolation (STI) features, local oxidation of silicon (LOCOS) features, other suitable isolation features, or a combination thereof.

As shown in FIG. 1A, the dielectric layer 112 is formed over the front surface S1 of the semiconductor substrate 111, in accordance with some embodiments. The wiring layers 113 and the conductive vias 114 are formed in the dielectric layer 112, in accordance with some embodiments. The conductive pads 115 are formed over the dielectric layer 112, in accordance with some embodiments.

The conductive vias 114 are electrically connected between different wiring layers 113, in accordance with some embodiments. The conductive vias 114 are electrically connected between the wiring layer 113 and the conductive pads 115, in accordance with some embodiments. The conductive vias 114 are electrically connected between the wiring layer 113 and the devices (which are formed in and/or over the semiconductor substrate 111), in accordance with some embodiments.

The dielectric layer 112 is made of a dielectric material, such as silicon oxide, silicon nitride, un-doped silicate glass (USG), or another suitable material, in accordance with some embodiments. The wiring layers 113 are made of a conductive material, such as metal (e.g., aluminum, copper, silver, gold, nickel, or tungsten) or alloys thereof, in accordance with some embodiments.

The conductive vias 114 are made of a conductive material, such as metal (e.g., aluminum, copper, silver, gold, nickel, or tungsten) or alloys thereof, in accordance with some embodiments. The conductive pads 115 are made of a conductive material, such as metal (e.g., aluminum, copper, silver, gold, nickel, or tungsten) or alloys thereof, in accordance with some embodiments.

As shown in FIG. 1A, the passivation layer 116 is formed over the dielectric layer 112 to cover edge portions of the conductive pads 115, in accordance with some embodiments. The passivation layer 116 has openings 116a partially exposing the conductive pads 115, in accordance with some embodiments.

The passivation layer 116 is made of a dielectric material, such as polyimide, silicon oxide, silicon nitride, un-doped silicate glass (USG), or another suitable material, in accordance with some embodiments. In some embodiments, the semiconductor substrate 111, the dielectric layer 112, the wiring layers 113, the conductive vias 114, the conductive pads 115, and the passivation layer 116 together form a chip structure 117.

The conductive bumps 118 are formed over the conductive pads 115 respectively, in accordance with some embodiments. In some embodiments, the conductive bumps 118 are made of a conductive material such as copper (Cu), an alloy thereof, or the combination thereof, in accordance with some embodiments. The conductive bumps 118 are formed using a plating process such as an electroplating process, in accordance with some embodiments.

The solder layer 119 is formed over the conductive bumps 118, in accordance with some embodiments. The solder layer 119 is made of tin (Sn), the like, alloys thereof, or another suitable conductive material with a melting point lower than that of the conductive bumps 118, in accordance with some embodiments. The solder layer 119 is formed using a plating process such as an electroplating process, in accordance with some embodiments.

As shown in FIG. 1B, a carrier substrate 120 is bonded to the chip 110 through a glue layer 130, in accordance with some embodiments. The thickness T120 of the carrier substrate 120 ranges from about 400 μm to about 600 μm, in accordance with some embodiments.

The thickness T130 of the glue layer 130 ranges from about 40 μm to about 80 μm, in accordance with some embodiments. The carrier substrate 120 is made of a rigid material such as a glass material, in accordance with some embodiments. The glue layer 130 is made of an adhesive material such as a polymer material, in accordance with some embodiments.

As shown in FIG. 1C, the chip 110 is flipped upside down, in accordance with some embodiments. As shown in FIG. 1C, a mask layer 140 is formed over the back surface S2 of the semiconductor substrate 111, in accordance with some embodiments. The mask layer 140 has openings 142, in accordance with some embodiments. The openings 142 expose portions of the semiconductor substrate 111, in accordance with some embodiments.

As shown in FIG. 1D, an etching mask 150 is disposed over the chip 110, in accordance with some embodiments. The etching mask 150 has openings 152, in accordance with some embodiments. The openings 152 are aligned with the openings 142 of the mask layer 140 respectively, in accordance with some embodiments.

As shown in FIG. 1D, an anisotropic etching process 160 is performed to remove the portions of the semiconductor substrate 111 from the back surface S2 through the openings 142, in accordance with some embodiments.

As shown in FIG. 1D, a recess 111a is formed in the semiconductor substrate 111 and under the openings 142 after the anisotropic etching process 160 is performed, in accordance with some embodiments. The anisotropic etching process 160 includes a plasma etching process, in accordance with some embodiments.

As shown in FIG. 1E, the mask layer 140 is removed, in accordance with some embodiments. As shown in FIG. 1E, the carrier substrate 120 and the glue layer 130 is removed, in accordance with some embodiments.

FIG. 1E-1 is a top view of the chip of FIG. 1E, in accordance with some embodiments. FIG. 1E is a cross-sectional view illustrating the chip along a sectional line I-I′ in FIG. 1E-1, in accordance with some embodiments. FIG. 1E-3 is a cross-sectional view illustrating the chip along a sectional line II-II′ in FIG. 1E-1, in accordance with some embodiments.

As shown in FIGS. 1E, 1E-1, and 1E-3, the semiconductor substrate 111 has pillars 111b and 111c and a peripheral ring portion 111d, in accordance with some embodiments. The peripheral ring portion 111d surrounds the recess 111a, in accordance with some embodiments.

The recess 111a has a bottom surface 111al, in accordance with some embodiments. The pillars 111b and 111c protrude from the bottom surface 111al of the recess 111a, in accordance with some embodiments. As shown in FIG. 1E-3, the top surface 111b1 of the pillar 111b, the top surface 111cl of the pillar 111c, and top surface 111d2 of the peripheral ring portion 111d are substantially level with the back surface S2 of the semiconductor substrate 111, in accordance with some embodiments. The pillars 111b and 111c and the peripheral ring portion 111d are spaced apart from each other by gaps G1, in accordance with some embodiments.

The thickness T111b of the pillar 111b ranges from about 180 μm to about 280 μm, in accordance with some embodiments. The ratio of the thickness T111b to the thickness T111 of the semiconductor substrate 111 ranges from about 0.2 to about 0.5, in accordance with some embodiments.

The thickness T111c of the pillar 111c ranges from about 180 μm to about 280 μm, in accordance with some embodiments. The ratio of the thickness T111c to the thickness T111 ranges from about 0.2 to about 0.5, in accordance with some embodiments.

The thickness T111d of the peripheral ring portion 111d ranges from about 180 μm to about 280 μm, in accordance with some embodiments. The ratio of the thickness T111d to the thickness T111 ranges from about 0.2 to about 0.5, in accordance with some embodiments.

If the ratio of the thickness T111b, 111c, or 111d to the thickness T111 of the semiconductor substrate 111 is less than 0.2, the heat dissipation efficiency of the cooling liquid flowing in the recess 111a in the subsequent process may be insufficient, in accordance with some embodiments.

If the ratio of the thickness T111b, 111c, or 111d to the thickness T111 is greater than 0.5, the plate portion 111p of the semiconductor substrate 111 may be too thin and easily cracked, in accordance with some embodiments.

As shown in FIG. 1E-3, the semiconductor substrate 111 having a plate portion 111p, in accordance with some embodiments. The peripheral ring portion 111d and the pillars 111b and 111c are over the plate portion 111p, in accordance with some embodiments. The peripheral ring portion 111d has an opening 111d1, in accordance with some embodiments. The pillars 111b and 111c are in the opening 111d1, in accordance with some embodiments.

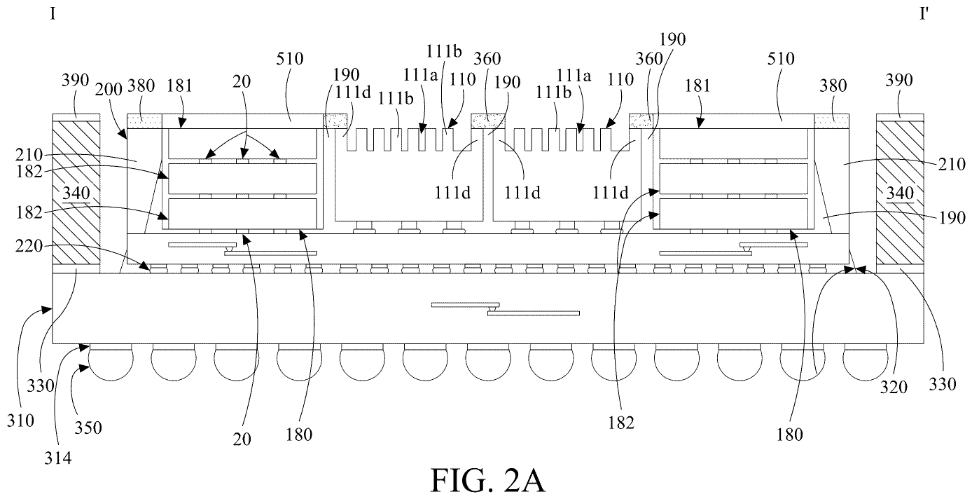

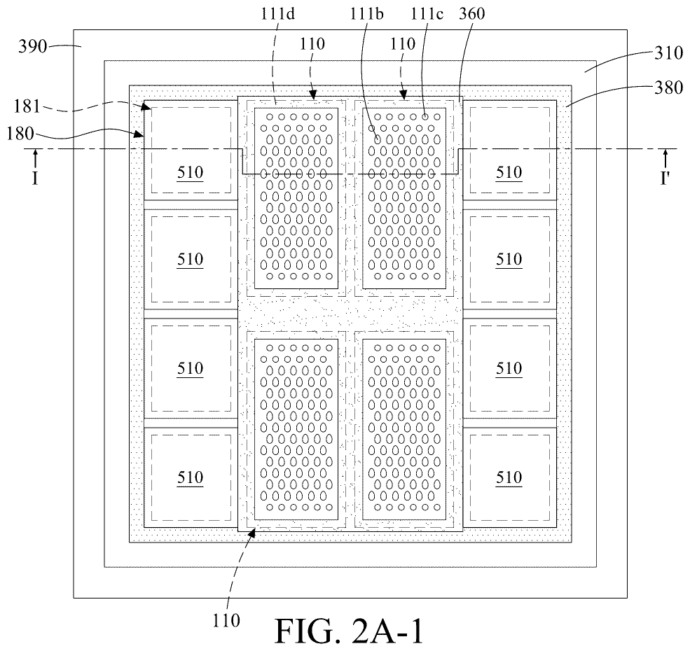

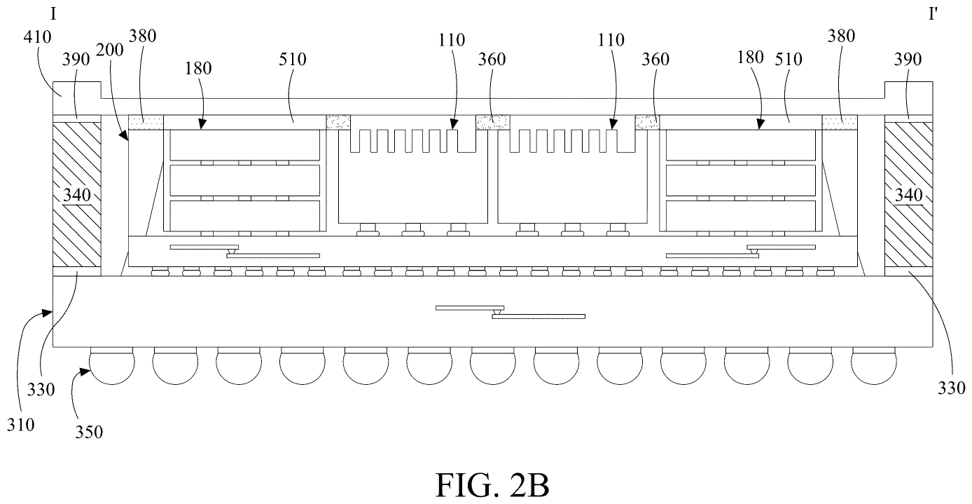

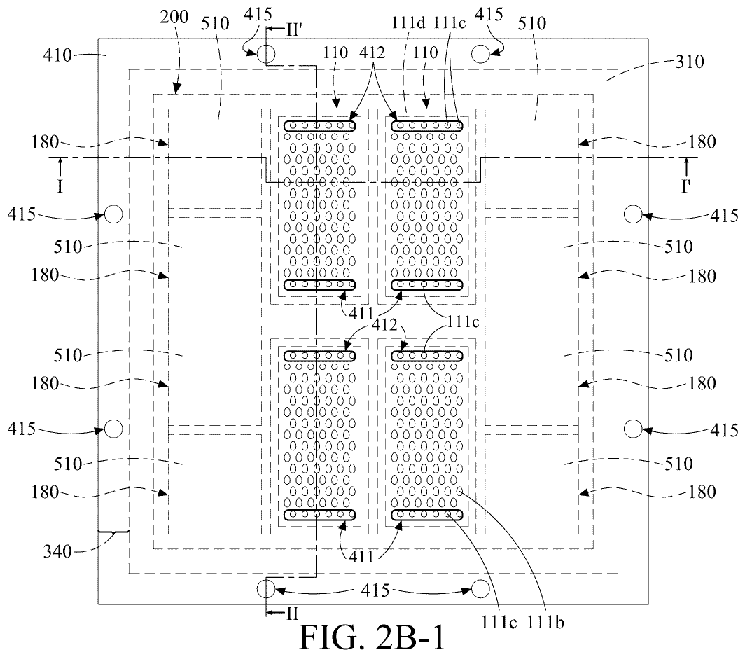

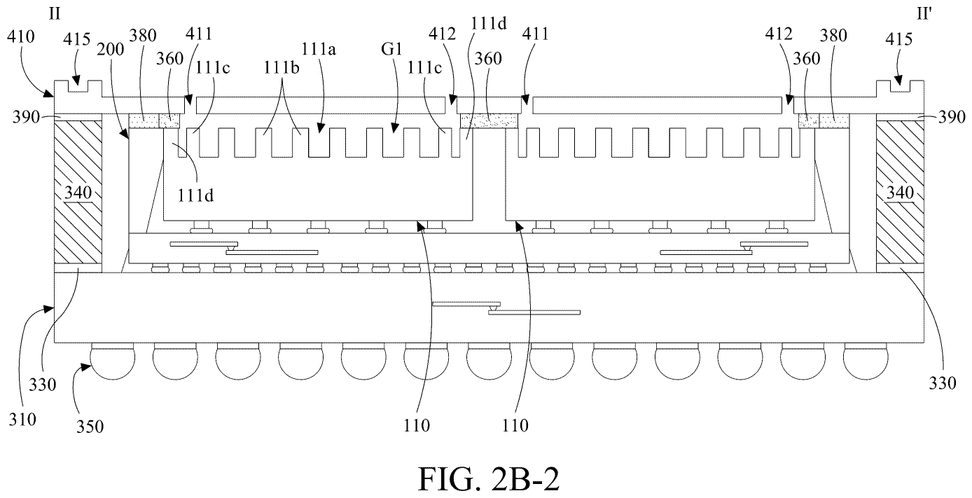

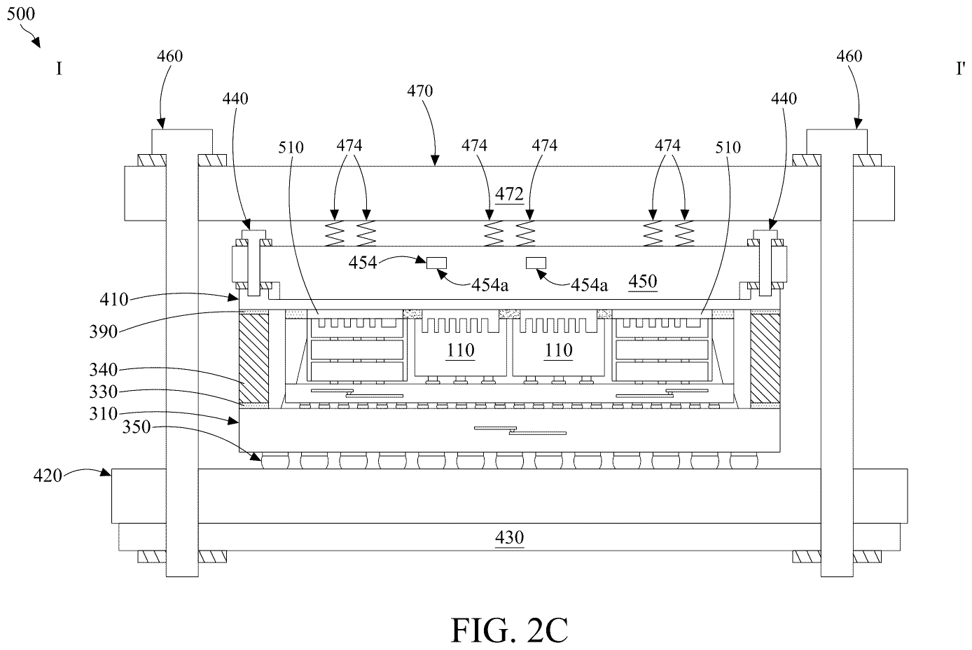

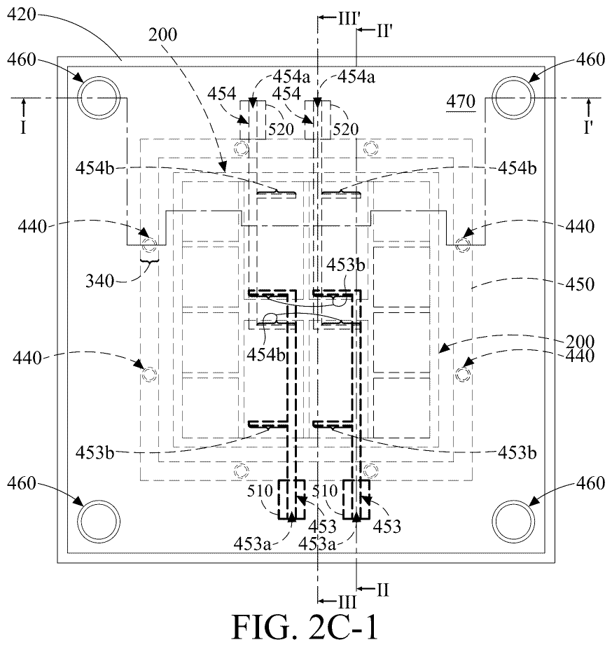

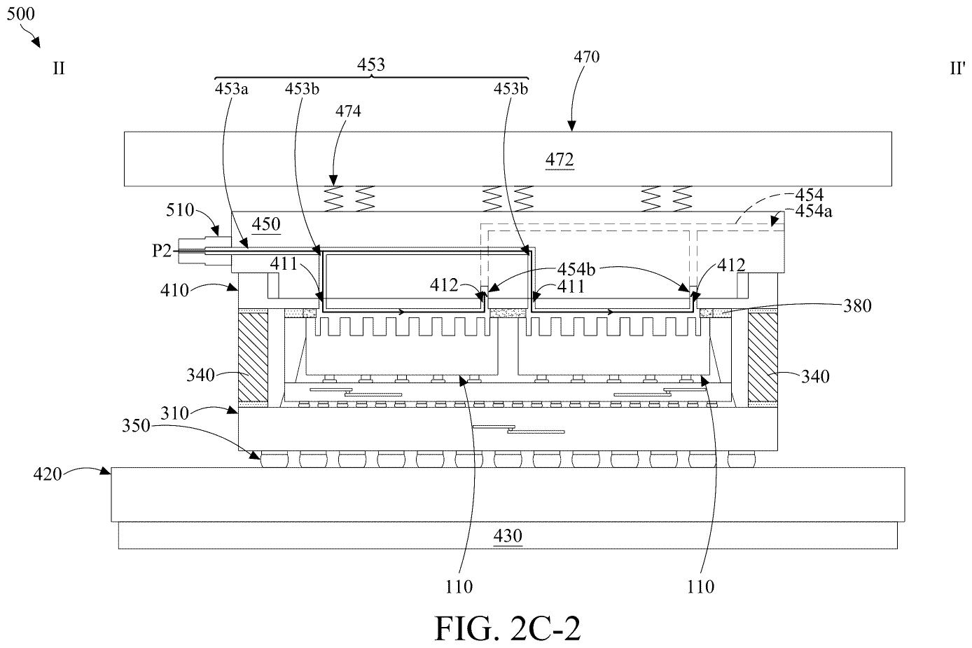

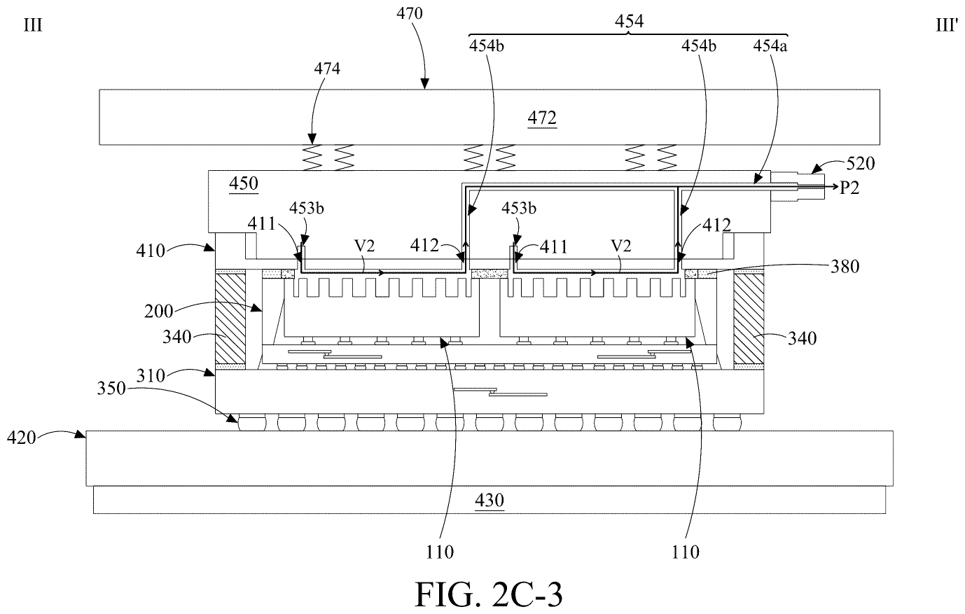

As shown in FIG. 1E-1, the pillar 111c has a round shape, in accordance with some embodiments. FIG. 1E-2 is a top view of the pillar 111b of the semiconductor substrate 111 of the chip 110 of FIG. 1E, in accordance with some embodiments. As shown in FIGS. 1E-1 and 1E-2, the pillar 111b has an egg-like shape, in accordance with some embodiments.

Since the pillars 111c and 111b have hydrodynamic friendly design (e.g., a round shape or an egg-like shape), this design can reduce the flow resistance of the cooling liquid flowing in the recess 111a of the semiconductor substrate 111 of the chip 110, thereby increasing the flow rate and heat dissipation efficiency of the cooling liquid, and reducing the power consumption of the pump that provides the cooling liquid, in accordance with some embodiments.

As shown in FIG. 1E-2, the pillar 111b has a narrow rounded end E1 and a wide rounded end E2, in accordance with some embodiments. The narrow rounded end E1 is opposite to the wide rounded end E2, in accordance with some embodiments. The length L111b of the pillar 111b is equal to the distance between the narrow rounded end E1 and the wide rounded end E2, in accordance with some embodiments.

The length L111b of the pillar 111b ranges from about 300 μm to about 400 μm, in accordance with some embodiments. As shown in FIGS. 1E-1 and 1E-2, the distance D111b1 between the wide rounded ends E2 of two adjacent pillars 111b ranges from about 800 μm to about 1000 μm, in accordance with some embodiments.

As shown in FIG. 1E-2, the pillar 111b has curved sidewalls S1 and S2, in accordance with some embodiments. The curved sidewall S1 is opposite to the curved sidewall S2, in accordance with some embodiments. The curved sidewall S1 is connected between the narrow rounded end E1 and the wide rounded end E2, in accordance with some embodiments. The curved sidewall S2 is connected between the narrow rounded end E1 and the wide rounded end E2, in accordance with some embodiments.

The width W111b of the pillar 111b is equal to the distance between the curved sidewalls S1 and S2, in accordance with some embodiments. The width W111b of the pillar 111b ranges from about 170 μm to about 270 μm, in accordance with some embodiments. As shown in FIGS. 1E-1 and 1E-2, the distance D111b2 between the curved sidewalls S1 of two adjacent pillars 111b ranges from about 400 μm to about 600 μm, in accordance with some embodiments.

The length L111b of the pillar 111b is greater than the width W111b of the pillar 111b, in accordance with some embodiments. As shown in FIG. 1E-2, the pillar 111b has a major axis A111b between the narrow rounded end E1 and the wide rounded end E2, in accordance with some embodiments.

The major axis A111b is parallel to a flow direction of the cooling liquid flowing in the recess 111a of the semiconductor substrate 111 of the chip 110 in the subsequent process, in accordance with some embodiments. The major axis A111b is also referred to as a long axis, in accordance with some embodiments.

In some embodiments, a direction V111b from the wide rounded end E2 to the narrow rounded end E1 is parallel to the flow direction of the cooling liquid flowing in the recess 111a of the semiconductor substrate 111 of the chip 110 in the subsequent process, which can reduce the flow resistance of the cooling liquid flowing in the recess 111a. As shown in FIG. 1E-2, the length L111b of the pillar 111b is greater than the length L111c of the pillar 111c, in accordance with some embodiments.

FIG. 1F-1 is a top view of the chip of FIG. 1F, in accordance with some embodiments. FIG. 1F is a cross-sectional view illustrating the chip along a sectional line I-I′ in FIG. 1F-1, in accordance with some embodiments. FIG. 1F-2 is a cross-sectional view illustrating the chip along a sectional line II-II′ in FIG. 1F-1, in accordance with some embodiments.

As shown in FIGS. 1F, 1F-1, and 1F-2, a chip 181 is provided, in accordance with some embodiments. The chip 181 is similar to the chip 110 of FIG. 1E-3, in accordance with some embodiments. The chip 181 includes a semiconductor substrate 11, a dielectric layer 12, wiring layers 13, conductive vias 14, conductive pads 15, a passivation layer 16, conductive bumps 18, and a solder layer 19, in accordance with some embodiments. The semiconductor substrate 11 has a front surface S1′ and a back surface S2′, in accordance with some embodiments.

As shown in FIGS. 1F, 1F-1, and 1F-2, the semiconductor substrate 11 has pillars 11b and 11c and a peripheral ring portion 11d, in accordance with some embodiments. The peripheral ring portion 11d surrounds the recess 11a, in accordance with some embodiments.

The recess 11a has a bottom surface 11al, in accordance with some embodiments. The pillars 11b and 11c protrude from the bottom surface 11al of the recess 11a, in accordance with some embodiments.

As shown in FIG. 1F-2, the top surface 11b1 of the pillar 11b, the top surface 11cl of the pillar 11c, and top surface 11d2 of the peripheral ring portion 11d are substantially level with the back surface S2′ of the semiconductor substrate 11, in accordance with some embodiments. The pillars 11b and 11c and the peripheral ring portion 11d are spaced apart from each other by gaps G2, in accordance with some embodiments.

The thickness T11b of the pillar 11b ranges from about 180 μm to about 280 μm, in accordance with some embodiments. The ratio of the thickness T11b to the thickness T11 of the semiconductor substrate 11 ranges from about 0.2 to about 0.5, in accordance with some embodiments.

The thickness T11c of the pillar 11c ranges from about 180 μm to about 280 μm, in accordance with some embodiments. The ratio of the thickness T11c to the thickness T11 ranges from about 0.2 to about 0.5, in accordance with some embodiments.

The thickness T11d of the peripheral ring portion 11d ranges from about 180 μm to about 280 μm, in accordance with some embodiments. The ratio of the thickness T11d to the thickness T11 ranges from about 0.2 to about 0.5, in accordance with some embodiments.

If the ratio of the thickness T11b, 11c, or 11d to the thickness T11 of the semiconductor substrate 11 is less than 0.2, the heat dissipation efficiency of the cooling liquid flowing in the recess 11a in the subsequent process may be insufficient, in accordance with some embodiments. If the ratio of the thickness T11b, 11c, or 11d to the thickness T11 is greater than 0.5, the plate portion 11p of the semiconductor substrate 11 may be too thin and easily cracked, in accordance with some embodiments.

As shown in FIG. 1F-2, the semiconductor substrate 11 having a plate portion 11p, in accordance with some embodiments. The peripheral ring portion 11d and the pillars 11b and 11c are over the plate portion 11p, in accordance with some embodiments. The peripheral ring portion 11d has an opening 11d1, in accordance with some embodiments. The pillars 11b and 11c are in the opening 11d1, in accordance with some embodiments.

As shown in FIG. 1F-1, the pillar 11c has a round shape, in accordance with some embodiments. As shown in FIG. 1F-1, the pillar 11b has an egg-like shape, in accordance with some embodiments.

Since the pillars 11c and 11b have hydrodynamic friendly design (e.g., a round shape or an egg-like shape), this design can reduce the flow resistance of the cooling liquid flowing in the recess 11a of the semiconductor substrate 11 of the chip 181, thereby increasing the flow rate and heat dissipation efficiency of the cooling liquid, and reducing the power consumption of the pump that provides the cooling liquid, in accordance with some embodiments.

As shown in FIG. 1F-1, the pillar 11b has a narrow rounded end E1′ and a wide rounded end E2′, in accordance with some embodiments. The narrow rounded end E1′ is opposite to the wide rounded end E2′, in accordance with some embodiments. The length L11b of the pillar 11b is equal to the distance between the narrow rounded end E1′ and the wide rounded end E2′, in accordance with some embodiments.

The length L11b of the pillar 11b ranges from about 300 μm to about 400 μm, in accordance with some embodiments. As shown in FIG. 1F-1, the distance D11b1 between the wide rounded ends E2′ of two adjacent pillars 11b ranges from about 800 μm to about 1000 μm, in accordance with some embodiments.

As shown in FIG. 1F-1, the pillar 11b has curved sidewalls S1′ and S2′, in accordance with some embodiments. The curved sidewall S1′ is opposite to the curved sidewall S2′, in accordance with some embodiments. The curved sidewall S1′ is connected between the narrow rounded end E1′ and the wide rounded end E2′, in accordance with some embodiments. The curved sidewall S2′ is connected between the narrow rounded end E1′ and the wide rounded end E2′, in accordance with some embodiments.

The width W11b of the pillar 11b is equal to the distance between the curved sidewalls S1′ and S2′, in accordance with some embodiments. The width W11b of the pillar 11b ranges from about 170 μm to about 270 μm, in accordance with some embodiments. As shown in FIGS. 1F-1 and 1F-1, the distance D11b2 between the curved sidewalls S1′ of two adjacent pillars 11b ranges from about 400 μm to about 600 μm, in accordance with some embodiments.

The length L11b of the pillar 11b is greater than the width W11b of the pillar 11b, in accordance with some embodiments. As shown in FIG. 1F-1, the pillar 11b has a major axis A11b between the narrow rounded end E1′ and the wide rounded end E2′, in accordance with some embodiments.

The major axis A11b is parallel to a flow direction of the cooling liquid flowing in the recess 11a of the semiconductor substrate 11 of the chip 181 in the subsequent process, in accordance with some embodiments. The major axis A11b is also referred to as a long axis, in accordance with some embodiments.

In some embodiments, a direction V11b from the wide rounded end E2′ to the narrow rounded end E1′ is parallel to the flow direction of the cooling liquid flowing in the recess 11a of the semiconductor substrate 11 of the chip 181 in the subsequent process, which can reduce the flow resistance of the cooling liquid flowing in the recess 11a. As shown in FIG. 1F-1, the length L11b of the pillar 11b is greater than the length L11c of the pillar 11c, in accordance with some embodiments.

In some embodiments, the semiconductor substrate 11 is made of an elementary semiconductor material including silicon or germanium in a single crystal structure, a polycrystal structure, or an amorphous structure.

In some other embodiments, the semiconductor substrate 11 is made of a compound semiconductor, such as silicon carbide, gallium arsenide, gallium phosphide, indium phosphide, indium arsenide, an alloy semiconductor, such as SiGe or GaAsP, or a combination thereof. The semiconductor substrate 11 may also include multi-layer semiconductors, semiconductor on insulator (SOI) (such as silicon on insulator or germanium on insulator), or a combination thereof.

In some embodiments, various devices (not shown) are formed in and/or over the semiconductor substrate 11. Examples of the various devices include active devices, passive devices, other suitable devices, or a combination thereof. The active devices may include transistors or diodes formed at a surface of the semiconductor substrate 11. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various devices. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 11. The isolation features are used to surround active regions and electrically isolate various devices formed in and/or over the semiconductor substrate 11 in the active regions. In some embodiments, the isolation features include shallow trench isolation (STI) features, local oxidation of silicon (LOCOS) features, other suitable isolation features, or a combination thereof.

As shown in FIG. 1A, the dielectric layer 12 is formed over the front surface S1′ of the semiconductor substrate 11, in accordance with some embodiments. The wiring layers 13 and the conductive vias 14 are formed in the dielectric layer 12, in accordance with some embodiments. The conductive pads 15 are formed over the dielectric layer 12, in accordance with some embodiments.

The conductive vias 14 are electrically connected between different wiring layers 13, in accordance with some embodiments. The conductive vias 14 are electrically connected between the wiring layer 13 and the conductive pads 15, in accordance with some embodiments. The conductive vias 14 are electrically connected between the wiring layer 13 and the devices (which are formed in and/or over the semiconductor substrate 11), in accordance with some embodiments.

The dielectric layer 12 is made of a dielectric material, such as silicon oxide, silicon nitride, un-doped silicate glass (USG), or another suitable material, in accordance with some embodiments. The wiring layers 13 are made of a conductive material, such as metal (e.g., aluminum, copper, silver, gold, nickel, or tungsten) or alloys thereof, in accordance with some embodiments.

The conductive vias 14 are made of a conductive material, such as metal (e.g., aluminum, copper, silver, gold, nickel, or tungsten) or alloys thereof, in accordance with some embodiments. The conductive pads 15 are made of a conductive material, such as metal (e.g., aluminum, copper, silver, gold, nickel, or tungsten) or alloys thereof, in accordance with some embodiments.

As shown in FIGS. 1F and 1F-2, the passivation layer 16 is formed over the dielectric layer 12 to cover edge portions of the conductive pads 15, in accordance with some embodiments. The passivation layer 16 has openings 16a partially exposing the conductive pads 15, in accordance with some embodiments.

The passivation layer 16 is made of a dielectric material, such as polyimide, silicon oxide, silicon nitride, un-doped silicate glass (USG), or another suitable material, in accordance with some embodiments. In some embodiments, the semiconductor substrate 11, the dielectric layer 12, the wiring layers 13, the conductive vias 14, the conductive pads 15, and the passivation layer 16 together form a chip structure 17.

The conductive bumps 18 are formed over the conductive pads 15 respectively, in accordance with some embodiments. In some embodiments, the conductive bumps 18 are made of a conductive material such as copper (Cu), an alloy thereof, or the combination thereof, in accordance with some embodiments. The conductive bumps 18 are formed using a plating process such as an electroplating process, in accordance with some embodiments.

The solder layer 19 is formed over the conductive bumps 18, in accordance with some embodiments. The solder layer 19 is made of tin (Sn), the like, alloys thereof, or another suitable conductive material with a melting point lower than that of the conductive bumps 18, in accordance with some embodiments.

The solder layer 19 is formed using a plating process such as an electroplating process, in accordance with some embodiments. The conductive bump 18 and the solder layer 19 thereover together formed a conductive connection structure 20, in accordance with some embodiments.

As shown in FIG. 1G, a chip 182 is provided, in accordance with some embodiments. The chip 182 is similar to the chip 181 of FIG. 1F-2, except that the chip 182 does not have the pillars 11b and 11c and the peripheral ring portion 11d of the chip 181 of FIG. 1F-2, and the chip 182 further has conductive vias structures 21 passing through the semiconductor substrate 11, in accordance with some embodiments.

Each conductive vias structure 21 has a dielectric layer 21a and a conductive plug 21b, in accordance with some embodiments. The dielectric layer 21a is between the conductive plug 21b and the semiconductor substrate 11, in accordance with some embodiments. The conductive plug 21b is electrically connected to the conductive vias 14 and the wiring layers 13, in accordance with some embodiments.

The dielectric layer 21a is made of a dielectric material, such as silicon oxide, silicon nitride, un-doped silicate glass (USG), or another suitable material, in accordance with some embodiments. The conductive plug 21b is made of a conductive material, such as metal (e.g., aluminum, copper, silver, gold, nickel, or tungsten) or alloys thereof, in accordance with some embodiments.

As shown in FIG. 1H, two chips 182 are provided, in accordance with some embodiments. One of the chips 182 is bonded to another one of the chips 182 through the conductive connection structures 20, in accordance with some embodiments. As shown in FIG. 1H, the chip 181 is bonded to the chip 182 through the conductive connection structures 20, in accordance with some embodiments.

As shown in FIG. 1H, a molding layer 183 is formed to surround the chips 181 and 182, in accordance with some embodiments. The chips 181 and 182 and the molding layer 183 together form a chip packages 180, in accordance with some embodiments. The chip packages 180 are also referred to as high bandwidth memory (HBM) packages, in accordance with some embodiments.

The molding layer 183 includes a polymer material or another suitable insulating material, in accordance with some embodiments. The polymer material includes thermosetting polymers, thermoplastic polymers, or mixtures thereof.

The polymer material includes, for example, plastic materials, epoxy resin, polyimide, polyethylene terephthalate (PET), polyvinyl chloride (PVC), polymethylmethacrylate (PMMA), polymer components doped with fillers including fiber, clay, silica, glass, ceramic, inorganic particles, or combinations thereof, in accordance with some embodiments.

FIG. 1I-1 is a top view of the chip package structure of FIG. 1I, in accordance with some embodiments. FIG. 1I is a cross-sectional view illustrating the chip along a sectional line I-I′ in FIG. 1I-1, in accordance with some embodiments.

As shown in FIGS. 1I and 11-1, the chips 110 and the chip packages 180 are provided, in accordance with some embodiments. As shown in FIGS. 1I and 11-1, the chips 110 and the chip packages 180 are bonded to a redistribution substrate 170, in accordance with some embodiments. The pillars 111b and 11b extend in a direction V0 away from the redistribution substrate 170, in accordance with some embodiments.

The redistribution substrate 170 includes a dielectric layer 171, wiring layers 172, conductive vias 173, and conductive pads 174, in accordance with some embodiments. The wiring layers 172 and the conductive vias 173 are formed in the dielectric layer 171, in accordance with some embodiments. The conductive pads 174 are formed under the dielectric layer 171, in accordance with some embodiments.

The conductive vias 173 are electrically connected between different wiring layers 172, in accordance with some embodiments. The conductive vias 173 are electrically connected between the wiring layer 172 and the conductive pads 174, in accordance with some embodiments.

The dielectric layer 171 is made of a dielectric material, such as silicon oxide, silicon nitride, un-doped silicate glass (USG), or another suitable material, in accordance with some embodiments. The wiring layers 172 are made of a conductive material, such as metal (e.g., aluminum, copper, silver, gold, nickel, or tungsten) or alloys thereof, in accordance with some embodiments.

The conductive vias 173 are made of a conductive material, such as metal (e.g., aluminum, copper, silver, gold, nickel, or tungsten) or alloys thereof, in accordance with some embodiments. The conductive pads 174 are made of a conductive material, such as metal (e.g., aluminum, copper, silver, gold, nickel, or tungsten) or alloys thereof, in accordance with some embodiments.

As shown in FIGS. 11 and 11-1, an underfill layer 190 is formed over the redistribution substrate 170 to surround the chips 110 and the chip packages 180, in accordance with some embodiments. The underfill layer 190 is formed between the chips 110, the chip packages 180, and the redistribution substrate 170, in accordance with some embodiments. The underfill layer 190 is made of an insulating material, such as a polymer material, in accordance with some embodiments.

As shown in FIGS. 11 and 11-1, a molding layer 210 is formed over the redistribution substrate 170 to surround the chips 110, the chip packages 180, and the underfill layer 190, in accordance with some embodiments. The top surface 111b1 of the pillar 111b, the top surface 111d2 of the peripheral ring portion 111d, the top surface 11b1 of the pillar 11b, the top surface 11d2 of the peripheral ring portion 11d, the top surface 186 of the chip package 180, the top surface 192 of the underfill layer 190, and the top surface 212 of the molding layer 210 are substantially level with each other, in accordance with some embodiments.

The molding layer 210 includes a polymer material or another suitable insulating material, in accordance with some embodiments. The polymer material includes thermosetting polymers, thermoplastic polymers, or mixtures thereof.

The polymer material includes, for example, plastic materials, epoxy resin, polyimide, polyethylene terephthalate (PET), polyvinyl chloride (PVC), polymethylmethacrylate (PMMA), polymer components doped with fillers including fiber, clay, silica, glass, ceramic, inorganic particles, or combinations thereof, in accordance with some embodiments.

As shown in FIG. 1I, conductive bumps 220 are formed over the conductive pads 174, in accordance with some embodiments. The conductive bumps 220 are made of tin (Sn), the like, alloys thereof, or another suitable conductive material, in accordance with some embodiments.

The chips 110, the chip packages 180, the redistribution substrate 170, the underfill layer 190, the molding layer 210, and the conductive bumps 220 together form a chip package 200, in accordance with some embodiments.

FIG. 1J-1 is a top view of the chip package structure of FIG. 1J, in accordance with some embodiments. FIG. 1J is a cross-sectional view illustrating the chip along a sectional line I-I′ in FIG. 1J-1, in accordance with some embodiments.

As shown in FIGS. 1J and 1J-1, the chip package 200 is bonded to a wiring substrate 310 through the conductive bumps 220, in accordance with some embodiments. The wiring substrate 310 includes a dielectric layer 311, wiring layers 312, conductive vias 313, and conductive pads 314, in accordance with some embodiments.

The wiring layers 312 and the conductive vias 313 are formed in the dielectric layer 311, in accordance with some embodiments. The conductive pads 314 are formed under the dielectric layer 311, in accordance with some embodiments.

The conductive vias 313 are electrically connected between different wiring layers 312, in accordance with some embodiments. The conductive vias 313 are electrically connected between the wiring layer 312 and the conductive pads 314, in accordance with some embodiments.

The dielectric layer 311 is made of a dielectric material, such as silicon oxide, silicon nitride, un-doped silicate glass (USG), or another suitable material, in accordance with some embodiments. The wiring layers 312 are made of a conductive material, such as metal (e.g., aluminum, copper, silver, gold, nickel, or tungsten) or alloys thereof, in accordance with some embodiments.

The conductive vias 313 are made of a conductive material, such as metal (e.g., aluminum, copper, silver, gold, nickel, or tungsten) or alloys thereof, in accordance with some embodiments. The conductive pads 314 are made of a conductive material, such as metal (e.g., aluminum, copper, silver, gold, nickel, or tungsten) or alloys thereof, in accordance with some embodiments.

As shown in FIG. 1J, an underfill layer 320 is formed between the redistribution substrate 170 and the wiring substrate 310, in accordance with some embodiments. The underfill layer 320 surrounds the redistribution substrate 170 and the conductive bumps 220, in accordance with some embodiments.

The underfill layer 320 is made of an insulating material, such as a polymer material, in accordance with some embodiments. For the sake of simplicity, FIG. 1J-1 does not show the underfill layer 320 of FIG. 1J, in accordance with some embodiments.

As shown in FIGS. 1J and 1J-1, an adhesive layer 330 is formed over the wiring substrate 310, in accordance with some embodiments. The adhesive layer 330 has an opening 332, in accordance with some embodiments.

The chip package 200 is in the opening 332, in accordance with some embodiments. The adhesive layer 330 surrounds the chip package 200, in accordance with some embodiments. The adhesive layer 330 is made of a polymer material or the like, in accordance with some embodiments.

As shown in FIGS. 1J and 1J-1, a ring structure 340 is bonded to the wiring substrate 310 through the adhesive layer 330, in accordance with some embodiments. The ring structure 340 is also referred to as an anti-warping ring structure, in accordance with some embodiments. The ring structure 340 is harder than the wiring substrate 310, thereby reducing the warpage of the wiring substrate 310, in accordance with some embodiments.

The ring structure 340 has an opening 342 over the opening 332 of the adhesive layer 330, in accordance with some embodiments. The chip package 200 is in the opening 342, in accordance with some embodiments. The ring structure 340 surrounds the chip package 200, in accordance with some embodiments. The ring structure 340 is made of a metal material or alloys thereof, in accordance with some embodiments.

As shown in FIGS. 1J and 1J-1, solder balls 350 are formed under the conductive pads 314 of the wiring substrate 310, in accordance with some embodiments. The solder balls 350 are made of tin (Sn), the like, alloys thereof, or another suitable conductive material, in accordance with some embodiments.

As shown in FIGS. 1J and 1J-1, a sealant 360 is formed over the peripheral ring portions 111d of the semiconductor substrates 111, the peripheral ring portions 11d of the semiconductor substrates 11, and the underfill layer 190 between the chips 110 and the chip packages 180, in accordance with some embodiments.

The sealant 360 is used to separate the cooling liquid from the underfill layer 190 to prevent the underfill layer 190 from absorbing the cooling liquid, in accordance with some embodiments. The sealant 360 has openings 362 and 364, in accordance with some embodiments.

The openings 362 expose central portions of the semiconductor substrates 111 respectively, in accordance with some embodiments. The openings 362 are over the recesses 111a of the semiconductor substrates 111, in accordance with some embodiments.

The openings 362 are over the openings 111d1 of the peripheral ring portions 111d, in accordance with some embodiments. The sealant 360 surrounds the pillars 111b and 111c of the semiconductor substrates 111, in accordance with some embodiments.

The openings 364 expose central portions of the semiconductor substrates 11 respectively, in accordance with some embodiments. The openings 364 are over the recesses 11a of the semiconductor substrates 11, in accordance with some embodiments. The sealant 360 surrounds the recesses 11a and 111a of the semiconductor substrates 11 and 111, in accordance with some embodiments.

The openings 364 are over the openings 11d1 of the peripheral ring portions 11d of the semiconductor substrates 11, in accordance with some embodiments. The sealant 360 surrounds the pillars 11b and 11c of the semiconductor substrates 11, in accordance with some embodiments. The sealant 360 is made of a polymer material, in accordance with some embodiments.

As shown in FIGS. 1J and 1J-1, a ring layer 380 is formed over the molding layer 210, in accordance with some embodiments. The ring layer 380 surrounds the sealant 360, in accordance with some embodiments. The ring layer 380 is made of a polymer material, in accordance with some embodiments.

As shown in FIGS. 1J and 1J-1, an adhesive layer 390 is formed over the ring layer 380, in accordance with some embodiments. The adhesive layer 390 is made of a polymer material, in accordance with some embodiments.

FIG. 1K-1 is a top view of the chip package structure of FIG. 1K, in accordance with some embodiments. FIG. 1K is a cross-sectional view illustrating the chip along a sectional line I-I′ in FIG. 1K-1, in accordance with some embodiments. For clarity, in FIG. 1K-1, the pillars 11b and 111b are shown using solid lines instead of dashed lines.

FIG. 1K-2 is a cross-sectional view illustrating the chip package structure along a sectional line II-II′ in FIG. 1K-1, in accordance with some embodiments. FIG. 1K-3 is a top view of a first region of the chip package structure of FIG. 1K-1, in accordance with some embodiments.

FIG. 1K-4 is a cross-sectional view illustrating the chip package structure along a sectional line III-III′ in FIG. 1K-1, in accordance with some embodiments. FIG. 1K-5 is a top view of a second region of the chip package structure of FIG. 1K-1, in accordance with some embodiments.

As shown in FIGS. 1K and 1K-1, a lid 410 is bonded to the chip package 200 and the ring structure 340 through the sealant 360, the ring layer 380, and the adhesive layer 390, in accordance with some embodiments. The lid 410 covers the ring structure 340 and the chip package 200, in accordance with some embodiments.

As shown in FIGS. 1K, 1K-1, 1K-2 and 1K-4, the lid 410 has liquid inlet trenches 411 and 413 and liquid outlet trenches 412 and 414, in accordance with some embodiments. The liquid inlet trenches 411 and 413 and liquid outlet trenches 412 and 414 pass through the lid 410, in accordance with some embodiments.

As shown in FIGS. 1K-1 and 1K-2, the liquid inlet trenches 413 and the liquid outlet trenches 414 are over the chips 181 of the chip packages 180, in accordance with some embodiments. The liquid inlet trenches 413 and the liquid outlet trenches 414 are over the pillars 11c, in accordance with some embodiments.

As shown in FIG. 1K-2, the liquid inlet trench 413 and the liquid outlet trench 414 connect the recess 11a of the semiconductor substrate 11 thereunder, in accordance with some embodiments. The liquid inlet trench 413 and the liquid outlet trench 414 connect the opening 11d1 of the peripheral ring portion 11d of the semiconductor substrate 11, in accordance with some embodiments. In some embodiments, one of the liquid inlet trenches 413 and one of the liquid outlet trenches 414 are over one of the chips 181.

As shown in FIGS. 1K-1 and 1K-4, the liquid inlet trenches 411 and the liquid outlet trenches 412 are over the chips 110, in accordance with some embodiments. The liquid inlet trenches 411 and the liquid outlet trenches 412 are over the pillars 111c, in accordance with some embodiments.

As shown in FIG. 1K-4, the liquid inlet trench 411 and the liquid outlet trench 412 connect the recess 111a of the semiconductor substrate 111 thereunder, in accordance with some embodiments.

The liquid inlet trench 411 and the liquid outlet trench 412 connect the opening 111d1 of the peripheral ring portion 111d of the semiconductor substrate 111, in accordance with some embodiments. In some embodiments, one of the liquid inlet trenches 411 and one of the liquid outlet trenches 412 are over one of the chips 110.

As shown in FIG. 1K-1, the liquid inlet trenches 411 and 413 have a stripe-like shape, in accordance with some embodiments. The liquid outlet trenches 412 and 414 have a stripe-like shape, in accordance with some embodiments. The sealant 360 is between the lid 410 and the chip 110, in accordance with some embodiments. As shown in FIGS. 1K-1 and 1K-4, the lid 410 has holes 415, in accordance with some embodiments. The lid 410 is made of metal or alloys thereof, in accordance with some embodiments.

As shown in FIGS. 1K-1 and 1K-3, in the region R1, a flow direction V1 of the cooling liquid flowing in the recess 11a (or the gaps G2) is from the liquid inlet trench 413 to the liquid outlet trench 414, in accordance with some embodiments.

A direction V11b1 from the wide rounded end E2′ to the narrow rounded end E1′ of the pillar 11b is parallel to the flow direction V1, which can reduce the flow resistance of the cooling liquid flowing in the recess 11a, in accordance with some embodiments.

The major axis A11b1 of the pillar 11b is parallel to the flow direction V1 of the cooling liquid flowing in the recess 11a between the liquid inlet trench 413 and the liquid outlet trench 414, in accordance with some embodiments. The major axis A11b1 is also referred to as a long axis, in accordance with some embodiments.

As shown in FIGS. 1K-1 and 1K-5, in the region R2, a flow direction V2 of the cooling liquid flowing in the recess 111a (or the gaps G1) is from the liquid inlet trench 411 to the liquid outlet trench 412, in accordance with some embodiments.

A direction V111b1 from the wide rounded end E2 to the narrow rounded end E1 of the pillar 111b is parallel to the flow direction V2, which can reduce the flow resistance of the cooling liquid flowing in the recess 111a, in accordance with some embodiments.

The major axis A111b1 of the pillar 111b is parallel to the flow direction V2 of the cooling liquid flowing in the recess 111a between the liquid inlet trench 411 and the liquid outlet trench 412, in accordance with some embodiments. The major axis A111b1 is also referred to as a long axis, in accordance with some embodiments.

As shown in FIG. 1L, the wiring substrate 310 is bonded to a wiring board 420 through the solder balls 350, in accordance with some embodiments. The wiring board 420 includes a dielectric layer, wiring layers, conductive vias, and conductive pads, in accordance with some embodiments. The wiring layers and the conductive vias are formed in the dielectric layer, in accordance with some embodiments. The conductive pads are formed under the dielectric layer, in accordance with some embodiments.

The conductive vias are electrically connected between different wiring layers, in accordance with some embodiments. The conductive vias are electrically connected between the wiring layer and the conductive pads, in accordance with some embodiments. The solder balls 350 are connected to the conductive pads, in accordance with some embodiments.

The dielectric layer is made of a dielectric material, such as silicon oxide, silicon nitride, un-doped silicate glass (USG), or another suitable material, in accordance with some embodiments. The wiring layers are made of a conductive material, such as metal (e.g., aluminum, copper, silver, gold, nickel, or tungsten) or alloys thereof, in accordance with some embodiments.

The conductive vias are made of a conductive material, such as metal (e.g., aluminum, copper, silver, gold, nickel, or tungsten) or alloys thereof, in accordance with some embodiments. The conductive pads are made of a conductive material, such as metal (e.g., aluminum, copper, silver, gold, nickel, or tungsten) or alloys thereof, in accordance with some embodiments.

As shown in FIG. 1L, the wiring board 420 is disposed over a backing plate 430, in accordance with some embodiments. The backing plate 430 is made of metal or alloys thereof, in accordance with some embodiments. FIG. 1L-1 is a top view of the chip package structure of FIG. 1L, in accordance with some embodiments. FIG. 1L is a cross-sectional view illustrating the chip along a sectional line I-I′ in FIG. 1L-1, in accordance with some embodiments.

As shown in FIGS. 1L and 1L-1, washers 441 are disposed over the holes 415 of the lid 410, in accordance with some embodiments. The washer 441 has an opening 441a, in accordance with some embodiments. The opening 441a is over the hole 415, in accordance with some embodiments. The washers 441 are made of metal, alloys thereof, or polymer, in accordance with some embodiments.

As shown in FIGS. 1L and 1L-1, a heat sink 450 is disposed over the lid 410, in accordance with some embodiments. The heat sink 450 has through holes TH, in accordance with some embodiments. The through holes TH are over the openings 441a of the washers 441, in accordance with some embodiments.

As shown in FIGS. 1L and 1L-1, washers 442 are disposed over the through holes TH of the heat sink 450, in accordance with some embodiments. The washer 442 has an opening 442a, in accordance with some embodiments. The opening 442a is over the through holes TH, in accordance with some embodiments. The washers 442 are made of metal, alloys thereof, or polymer, in accordance with some embodiments.

As shown in FIGS. 1L and 1L-1, pillar structures 443 are disposed in the openings 442a of the washers 442, the through holes TH of the heat sink 450, the openings 441a of the washers 441, and the holes 415 in the lid 410, in accordance with some embodiments. Each pillar structure 443 passes through the washer 442, the heat sink 450, and the washer 441 and extends into the lid 410, in accordance with some embodiments.

The pillar structures 443 are also referred to as screw structures, in accordance with some embodiments. The pillar structures 443 are used to fix the heat sink 450 on the lid 410, in accordance with some embodiments. The pillar structures 443 are made of a hard material such as a metal material or a polymer material, in accordance with some embodiments. The washers 441 and 442 and the pillar structure 443 passing through the washers 441 and 442 together form a fixing structure 440, in accordance with some embodiments.

As shown in FIGS. 1L and 1L-1, washers 461 are disposed under the backing plate 430, in accordance with some embodiments. The washers 461 have openings 461a, in accordance with some embodiments. The openings 461a are under the through holes 432 of the backing plate 430 and the through holes 422 of the wiring board 420, in accordance with some embodiments. The washers 461 are made of metal, alloys thereof, or polymer, in accordance with some embodiments.

As shown in FIGS. 1L and 1L-1, a fixture structure 470 is disposed over the heat sink 450, in accordance with some embodiments. The fixture structure 470 comprises a fixture plate 472 and springs 474, in accordance with some embodiments. The springs 474 are between the fixture plate 472 and the heat sink 450, in accordance with some embodiments. The fixture plate 472 is made of metal or alloys thereof, in accordance with some embodiments. The springs 474 are made of metal, alloys thereof, or polymer, in accordance with some embodiments.

As shown in FIGS. 1L and 1L-1, washers 462 are disposed over the fixture plate 472, in accordance with some embodiments. The washers 462 have openings 462a, in accordance with some embodiments. The openings 462a are over the through holes 472a of the fixture plate 472, in accordance with some embodiments. The washers 462 are made of metal, alloys thereof, or polymer, in accordance with some embodiments.

As shown in FIGS. 1L and 1L-1, pillar structures 463 are disposed in the openings 462a of the washers 462, the through holes 472a of the fixture plate 472, the through holes 422 of the wiring board 420, the through holes 432 of the backing plate 430, and the openings 461a of the washers 461, in accordance with some embodiments. Each pillar structure 463 passes through the washer 462, the fixture plate 472, the wiring board 420, the backing plate 430, and the washer 461, in accordance with some embodiments.

The pillar structures 463 are also referred to as screw structures, in accordance with some embodiments. The pillar structures 463 are used to fix the fixture structure 470 on the heat sink 450, in accordance with some embodiments.

The pillar structures 463 are made of a hard material such as a metal material or a polymer material, in accordance with some embodiments. The washers 461 and 462 and the pillar structure 463 passing through the washers 461 and 462 together form a fixing structure 460, in accordance with some embodiments.

FIG. 1L-2 is a cross-sectional view illustrating the chip package structure along a sectional line II-II′ in FIG. 1L-1, in accordance with some embodiments. FIG. 1L-3 is a cross-sectional view illustrating the chip package structure along a sectional line III-III′ in FIG. 1L-1, in accordance with some embodiments.

As shown in FIGS. 1L-1, 1L-2, and 1L-3, the heat sink 450 has a liquid inlet channel 451 and a liquid outlet channel 452, in accordance with some embodiments. The liquid inlet channel 451 and the liquid outlet channel 452 pass through the heat sink 450, in accordance with some embodiments.

The liquid inlet trenches 413 of the lid 410 connect the liquid inlet channel 451 of the heat sink 450, in accordance with some embodiments. The liquid outlet trenches 414 of the lid 410 connect the liquid outlet channel 452 of the heat sink 450, in accordance with some embodiments.

The liquid inlet channel 451 and the liquid outlet channel 452 connect the recesses 11a of the chips 181 of the chip packages 180, in accordance with some embodiments. The liquid inlet channel 451 and the liquid outlet channel 452 connect the gaps G2 between the pillars 11b and 11c and the peripheral ring portion 11d of the chips 181 of the chip packages 180, in accordance with some embodiments.

The liquid inlet channel 451 and the liquid outlet channel 452 connect the openings 11d1 of the peripheral ring portions 11d of the chips 181 of the chip packages 180, in accordance with some embodiments.

The liquid inlet channel 451 has a main portion 451a and branch portions 451b, in accordance with some embodiments. The main portion 451a connects the branch portions 451b, in accordance with some embodiments.

The main portion 451a extends laterally across the chip packages 180, in accordance with some embodiments. The branch portions 451b extend vertically toward the lid 410, in accordance with some embodiments. The branch portions 451b respectively connect the liquid inlet trenches 413 of the lid 410, in accordance with some embodiments.

The liquid outlet channel 452 has a main portion 452a and branch portions 452b, in accordance with some embodiments. The main portion 452a connects the branch portions 452b, in accordance with some embodiments.

The main portion 452a extends laterally across the chip packages 180, in accordance with some embodiments. The branch portions 452b extend vertically toward the lid 410, in accordance with some embodiments. The branch portions 452b respectively connect the liquid outlet trenches 414 of the lid 410, in accordance with some embodiments.

In some embodiments, one of the branch portions 451b and one of the branch portions 452b are over one of the chips 181. Over one of the chips 181, the cooling liquid (not shown) flows along the path P1 and therefore sequentially passes through the liquid inlet channel 451, the recess 11a the chip 181 (or the gap G2 between the pillars 11b and 11c and the peripheral ring portion 11d), and the liquid outlet channel 452, in accordance with some embodiments.

When the cooling liquid flows in the recess 11a of the chip 181 between the branch portion 451b of the liquid inlet channel 451 and the branch portion 452b of the liquid outlet channel 452 (or between the liquid inlet trench 413 and the liquid outlet trench 414), the cooling liquid flows in the flow direction V1, in accordance with some embodiments.

FIG. 1L-4 is a top view of the chip package structure of FIG. 1L, in accordance with some embodiments. Since there are many cross-sectional views of the chip package structure of FIG. 1L, for clarity, the application uses the same top views of FIGS. 1L-1 and 1L-4 to respectively show different sectional lines corresponding to different cross-sectional views of the chip package structure.

FIG. 1L-5 is a cross-sectional view illustrating the chip package structure along a sectional line IV-IV′ in FIG. 1L-4, in accordance with some embodiments. FIG. 1L-6 is a cross-sectional view illustrating the chip package structure along a sectional line V-V′ in FIG. 1L-4, in accordance with some embodiments.

As shown in FIGS. 1L-4, 1L-5, and 1L-6, the heat sink 450 has a liquid inlet channel 453 and a liquid outlet channel 454, in accordance with some embodiments. The liquid inlet channel 453 and the liquid outlet channel 454 pass through the heat sink 450, in accordance with some embodiments.

The liquid inlet trenches 411 of the lid 410 connect the liquid inlet channel 453 of the heat sink 450, in accordance with some embodiments. The liquid outlet trenches 412 of the lid 410 connect the liquid outlet channel 454 of the heat sink 450, in accordance with some embodiments.

The liquid inlet channel 453 and the liquid outlet channel 454 connect the recesses 111a of the chips 110, in accordance with some embodiments. The liquid inlet channel 453 and the liquid outlet channel 454 connect the gaps G1 between the pillars 111b and 111c and the peripheral ring portion 111d of the chips 110, in accordance with some embodiments. The liquid inlet channel 453 and the liquid outlet channel 454 connect the openings 111d1 of the peripheral ring portions 111d of the chips 110, in accordance with some embodiments.

The liquid inlet channel 453 has a main portion 453a and branch portions 453b, in accordance with some embodiments. The main portion 453a connects the branch portions 453b, in accordance with some embodiments. The main portion 453a extends laterally across the chip 110, in accordance with some embodiments.

The branch portions 453b extend vertically toward the lid 410, in accordance with some embodiments. The branch portions 453b respectively connect the liquid inlet trenches 411 of the lid 410, in accordance with some embodiments.

The liquid outlet channel 454 has a main portion 454a and branch portions 454b, in accordance with some embodiments. The main portion 454a connects the branch portions 454b, in accordance with some embodiments. The main portion 454a extends laterally across the chip 110, in accordance with some embodiments.

The branch portions 454b extend vertically toward the lid 410, in accordance with some embodiments. The branch portions 454b respectively connect the liquid outlet trenches 412 of the lid 410, in accordance with some embodiments.

In some embodiments, one of the branch portions 453b and one of the branch portions 454b are over one of the chips 110. Over one of the chips 110, the cooling liquid (not shown) flows along the path P2 and therefore sequentially passes through the liquid inlet channel 453, the recess 111a the chip 110 (or the gap G1 between the pillars 111b and 111c and the peripheral ring portion 111d), and the liquid outlet channel 454, in accordance with some embodiments.

When the cooling liquid flows in the recess 111a of the chip 110 between the branch portion 453b of the liquid inlet channel 453 and the branch portion 454b of the liquid outlet channel 454 (or between the liquid inlet trench 411 and the liquid outlet trench 412), the cooling liquid flows in the flow direction V2, in accordance with some embodiments.

FIG. 1L-7 is a cross-sectional view illustrating the chip package structure along a sectional line VI-VI′ in FIG. 1L-4, in accordance with some embodiments. As shown in FIG. 1L-7, a width W1 of the branch portion 452b of the liquid outlet channel 452 increases toward the liquid outlet trench 414 of the lid 410, in accordance with some embodiments. The branch portion 452b has a trapezoid shape, in accordance with some embodiments.

As shown in FIG. 1L-7, a width W2 of the branch portion 454b of the liquid outlet channel 454 increases toward the liquid outlet trench 412 of the lid 410, in accordance with some embodiments. The branch portion 454b has a trapezoid shape, in accordance with some embodiments.

FIG. 1L-8 is a cross-sectional view illustrating the chip package structure along a sectional line VII-VII′ in FIG. 1L-4, in accordance with some embodiments. As shown in FIG. 1L-8, a width W3 of the branch portion 451b increases toward the liquid inlet trench 413, in accordance with some embodiments. The branch portion 451b has a trapezoid shape, in accordance with some embodiments.

As shown in FIG. 1L-8, a width W4 of the branch portion 453b increases toward the liquid inlet trench 411, in accordance with some embodiments. The branch portion 453b has a trapezoid shape, in accordance with some embodiments. The heat sink 450 is made of a heat conductive material such as metal (e.g., Al) or alloys thereof, in accordance with some embodiments. In this step, a chip package structure 400 is substantially formed, in accordance with some embodiments.

Since the application forms the recesses 11a in the semiconductor substrates 11 of the chips 181 and the recesses 111a in the semiconductor substrates 111 of the chips 110, the cooling liquid flowing in the recesses 11a and 111a can be close to the hot spots (e.g., the devices formed at the front surface of the semiconductor substrate), which can improve the heat dissipation efficiency, in accordance with some embodiments.

FIGS. 2A-2C are cross-sectional views of various stages of a process for forming a chip package structure, in accordance with some embodiments. FIG. 2A is a cross-sectional view illustrating the chip along a sectional line I-I′ in FIG. 2A-1, in accordance with some embodiments. FIG. 2A-1 is a top view of the chip package structure of FIG. 2A, in accordance with some embodiments.

As shown in FIGS. 2A and 2A-1, the chip package structure is similar to the chip package structure of FIG. 1J, except that the chips 181 of FIG. 2A do not have the recesses 11a of the chips 181 of FIG. 1J, and the chip package structure of FIG. 2A further has a heat conductive layer 510, in accordance with some embodiments.

The heat conductive layer 510 is formed over the chip packages 180, in accordance with some embodiments. The heat conductive layer 510 is made of a heat conductive material such as indium (In), tin (Sn), or an appropriate material with a good thermal conductivity and thermal diffusivity, in accordance with some embodiments.

The material of the heat conductive layer 510 has a thermal conductivity greater than or equal to 50 W/(m·K), in accordance with some embodiments. The thermal conductivity of the material of the heat conductive layer 510 is greater than that of the sealant 360, the chip package 180, the underfill layer 190, and the molding layer 210, in accordance with some embodiments.

FIG. 2B-1 is a top view of the chip package structure of FIG. 2B, in accordance with some embodiments. FIG. 2B is a cross-sectional view illustrating the chip along a sectional line I-I′ in FIG. 2B-1, in accordance with some embodiments. FIG. 2B-2 is a cross-sectional view illustrating the chip package structure along a sectional line II-II′ in FIG. 2B-1, in accordance with some embodiments.

As shown in FIGS. 2B, 2B-1 and 2B-2, the step of FIG. 1K is performed to bond the lid 410 to the chip package 200 and the ring structure 340 through the sealant 360, the ring layer 380, and the adhesive layer 390, in accordance with some embodiments.

FIG. 2C-1 is a top view of the chip package structure of FIG. 2C, in accordance with some embodiments. FIG. 2C is a cross-sectional view illustrating the chip along a sectional line I-I′ in FIG. 2C-1, in accordance with some embodiments.

FIG. 2C-2 is a cross-sectional view illustrating the chip package structure along a sectional line II-II′ in FIG. 2C-1, in accordance with some embodiments. FIG. 2C-3 is a cross-sectional view illustrating the chip package structure along a sectional line III-III′ in FIG. 2C-1, in accordance with some embodiments.

As shown in FIGS. 2C, 2C-1, 2C-2 and 2C-3, the step of FIG. 1L is performed to form the wiring board 420, the backing plate 430, the fixing structures 440, the heat sink 450, the fixing structures 460, and the fixture structures 470, in accordance with some embodiments.

Processes and materials for forming the chip package structure 500 may be similar to, or the same as, those for forming the chip package structure 400 described above. Elements designated by the same or similar reference numbers as those in FIGS. 1A to 2C-3 have the same or similar structures and the materials. Therefore, the detailed descriptions thereof will not be repeated herein.

In accordance with some embodiments, chip package structures and methods for forming the same are provided. The methods (for forming the chip package structure) form a recess in a back surface of a semiconductor substrate of a chip. Therefore, a cooling liquid can flow in the recess to be close to the hot spots (e.g., devices formed at a front surface of the semiconductor substrate of the chip), which can improve the heat dissipation efficiency.

In accordance with some embodiments, a method for forming a chip package structure is provided. The method includes providing a chip having a semiconductor substrate having a front surface and a back surface. The method includes partially removing the semiconductor substrate from the back surface to form a recess in the semiconductor substrate. The method includes bonding a heat sink to the chip. The heat sink has a first channel and a second channel, and the first channel and the second channel pass through the heat sink and connect the recess.

In accordance with some embodiments, a method for forming a chip package structure is provided. The method includes providing a first chip having a semiconductor substrate having a plate portion and a peripheral ring portion over the plate portion. The peripheral ring portion has a first opening. The method includes bonding a heat sink to the first chip. The heat sink has a first channel and a second channel, and the first channel and the second channel pass through the heat sink and connect the first opening.

In accordance with some embodiments, a chip package structure is provided. The chip package structure includes a first chip having a semiconductor substrate having a recess. The chip package structure includes. The chip package structure includes a heat sink over the first chip. The heat sink has a liquid inlet channel and a liquid outlet channel, and the liquid inlet channel and the liquid outlet channel pass through the heat sink and connect the recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
providing a chip having a semiconductor substrate having a front surface and a back surface;
partially removing the semiconductor substrate from the back surface to form a recess in the semiconductor substrate; and
bonding a heat sink to the chip, wherein the heat sink has a first channel and a second channel, and the first channel and the second channel pass through the heat sink and connect the recess.

2. The method for forming the chip package structure as claimed in claim 1, wherein after the semiconductor substrate is partially removed, the semiconductor substrate has a pillar protruding from a bottom surface of the recess, and a top surface of the pillar is substantially level with the back surface of the semiconductor substrate.

3. The method for forming the chip package structure as claimed in claim 1, further comprising:
before bonding the heat sink to the chip, bonding a lid to the chip, wherein the lid has a first trench and a second trench passing through the lid, the first trench and the second trench connect the first channel and the second channel of the heat sink respectively, and the first trench and the second trench connect the recess of the semiconductor substrate.

4. The method for forming the chip package structure as claimed in claim 3, wherein the first trench has a stripe-like shape.

5. The method for forming the chip package structure as claimed in claim 4, wherein the first channel of the heat sink has a branch portion connecting the first trench of the lid, and a width of the branch portion increases toward the first trench.

6. The method for forming the chip package structure as claimed in claim 5, wherein the branch portion of the first channel of the heat sink has a trapezoid shape in a cross-sectional view of the heat sink.

7. The method for forming the chip package structure as claimed in claim 3, further comprising:
before bonding the heat sink to the chip, forming a sealant over the chip, wherein the sealant has an opening over the recess of the semiconductor substrate, and the sealant is between the lid and the chip.

8. The method for forming the chip package structure as claimed in claim 1, further comprising:
bonding the chip to a redistribution substrate before the heat sink is bonded to the chip; and
forming a molding layer over the redistribution substrate and surrounding the chip before the heat sink is bonded to the chip.

9. The method for forming the chip package structure as claimed in claim 8, further comprising:
forming a ring layer over the molding layer before the heat sink is bonded to the chip, wherein the ring layer is between the heat sink and the molding layer.

10. The method for forming the chip package structure as claimed in claim 1, wherein after the semiconductor substrate is partially removed, the semiconductor substrate has a pillar protruding from a bottom surface of the recess, and the pillar has an egg-like shape.

11. A method for forming a chip package structure, comprising:
providing a first chip having a semiconductor substrate having a plate portion and a peripheral ring portion over the plate portion, wherein the peripheral ring portion has a first opening; and
bonding a heat sink to the first chip, wherein the heat sink has a first channel and a second channel, and the first channel and the second channel pass through the heat sink and connect the first opening.

12. The method for forming the chip package structure as claimed in claim 11, further comprising:
before bonding the heat sink to the first chip, forming a sealant over the peripheral ring portion of the first chip, wherein the sealant has a second opening over the first opening of the peripheral ring portion, and the sealant is between the heat sink and the first chip.

13. The method for forming the chip package structure as claimed in claim 11, further comprising:
before bonding the heat sink to the chip, bonding the first chip to a second chip.

14. The method for forming the chip package structure as claimed in claim 11, further comprising:
before bonding the heat sink to the chip, bonding a lid to the chip, wherein the lid has a first trench and a second trench passing through the lid, the first trench and the second trench connect the first channel and the second channel of the heat sink respectively, and the first trench and the second trench connect the first opening of the peripheral ring portion of the semiconductor substrate.

15. The method for forming the chip package structure as claimed in claim 14, wherein the semiconductor substrate further has a pillar over the plate portion and in the first opening of the peripheral ring portion, and a long axis of the pillar is substantially parallel to a direction from the first trench to the second trench of the lid in a top view of the chip and the lid.

16. A first chip package structure, comprising:
a first chip having a semiconductor substrate having a recess; and
a heat sink over the first chip, wherein the heat sink has a liquid inlet channel and a liquid outlet channel, and the liquid inlet channel and the liquid outlet channel pass through the heat sink and connect the recess.

17. The first chip package structure as claimed in claim 16, further comprising:
a lid between the first chip and the heat sink, wherein the lid has a first trench and a second trench passing through the lid, the first trench and the second trench connect the liquid inlet channel and the liquid outlet channel of the heat sink respectively, and the first trench and the second trench connect the recess of the semiconductor substrate.

18. The first chip package structure as claimed in claim 17, wherein the liquid inlet channel of the heat sink has a branch portion connecting the first trench of the lid, and a width of the branch portion increases toward the first trench.

19. The chip package structure as claimed in claim 16, further comprising:
a second chip under the first chip.

20. The chip package structure as claimed in claim 16, further comprising:
a sealant between the first chip and the heat sink and surrounding the recess of the semiconductor substrate of the first chip.
